(19) United States
(12) Patent Application Publication
(10) Pub. No.: US 2026/0198085 A1
(43) Pub. Date: Jul. 9, 2026

(54) SEMICONDUCTOR DEVICE AND METHOD FOR FABRICATING THEREOF

(71) Applicant: SAMSUNG ELECTRONICS CO., LTD., Suwon-si (KR)

(72) Inventors: Deok Hwan KIM, Suwon-si (KR); Han Byul CHOI, Suwon-si (KR)

(73) Assignee: SAMSUNG ELECTRONICS CO., LTD., Suwon-si (KR)

(21) Appl. No.: 19/350,673

(22) Filed: Oct. 6, 2025

(30) Foreign Application Priority Data
Jan. 9, 2025 (KR) 10-2025-0003434

(51) Int. Cl. H10D 84/85; H10D 84/01

(52) U.S. Cl. CPC H10D 84/851; H10D 84/0167; H10D 84/017; H10D 84/0186

(57) ABSTRACT

A semiconductor device includes: first and second source/drain patterns on a first side of a back wiring line; a channel pattern between the first and second source/drain patterns; a back source/drain contact between the first source/drain pattern and the back wiring line; and a sacrificial semiconductor pattern between the second source/drain pattern and the back wiring line, and in contact with the second source/drain pattern. A height from the first side of the back wiring line to a lowermost portion of the first source/drain pattern is greater than a height from the first side of the back wiring line to a lowermost portion of the second source/drain pattern. The back source/drain contact includes a first side connected to the first source/drain pattern, and a second side connected to the back wiring line. The first side of the back source/drain contact has a concave shape.

### CROSS-REFERENCE TO RELATED APPLICATION

This application claims priority from Korean Patent Application No. 10-2025-0003434, filed on Jan. 9, 2025, in the Korean Intellectual Property Office, the disclosure of which is incorporated by reference herein in its entirety.

### BACKGROUND

### 1. Field

The present disclosure relates to a semiconductor device and a method for fabricating thereof.

### 2. Description of Related Art

A multi-gate transistor may increase density of semiconductor device. The multi-gate transistor may include a multi-channel active pattern (or a silicon body) having a fin or nanowire shape formed on a substrate and a gate formed on a surface of the multi-channel active pattern.

Because such a multi-gate transistor utilizes a three-dimensional channel, scaling is easily performed. Further, even if a gate length of the multi-gate transistor is not increased, current control capability may be improved. Furthermore, a short channel effect (SCE) in which potential of a channel region is influenced by a drain voltage may be effectively suppressed.

On the other hand, as a pitch size of semiconductor device decreases, research for reducing the capacitance between the contacts in the semiconductor device and ensuring electrical stability is required.

### SUMMARY

One or more embodiments provide a semiconductor device capable of improving element performance and reliability.

One or more embodiments also provide a method for fabricating a semiconductor device capable of improving element performance and degree of integration of the element.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of an embodiment, a semiconductor device includes: a back interlayer insulating film; a back wiring line inside the back interlayer insulating film, wherein the back wiring line includes a first side and a second side opposite to the first side along a first direction; a first source/drain pattern on the first side of the back wiring line; a second source/drain pattern on the first side of the back wiring line, and spaced apart from the first source/drain pattern along a second direction; a channel pattern between the first source/drain pattern and the second source/drain pattern, and connected to the first source/drain pattern and the second source/drain pattern; a back source/drain contact between the first source/drain pattern and the back wiring line, and connected to the first source/drain pattern, wherein the back/source drain contact overlaps the first source/drain pattern along the first direction; a sacrificial semiconductor pattern between the second source/drain pattern and the back wiring line, and in contact with the second source/drain pattern; a front wiring line on the first source/drain pattern and the second source/drain pattern, and connected to the second source/drain pattern; and a front source/drain contact between the front wiring line and the second source/drain pattern. A height from the first side of the back wiring line to a lowermost portion of the first source/drain pattern is greater than a height from the first side of the back wiring line to a lowermost portion of the second source/drain pattern. The back source/drain contact includes a first side connected to the first source/drain pattern, and a second side which is opposite to the first side of the back source/drain contact along the first direction and connected to the back wiring line. The first side of the back source/drain contact has a concave shape.

According to another aspect of an embodiment, a semiconductor device includes: a back interlayer insulating film; a back wiring line inside the back interlayer insulating film, and includes a first side and a second side opposite to the first side along a first direction; a first source/drain pattern on the first side of the back wiring line; a second source/drain pattern on the first side of the back wiring line, and spaced apart from the first source/drain pattern along a second direction; a channel pattern between the first source/drain pattern and the second source/drain pattern, and connected to the first source/drain pattern and the second source/drain pattern; a back source/drain contact between the first source/drain pattern and the back wiring line, and connected to the first source/drain pattern, wherein the back source/drain contact overlaps the first source/drain pattern along the first direction; a back contact silicide film between the back source/drain contact and the first source/drain pattern; a sacrificial semiconductor pattern between the second source/drain pattern and the back wiring line, and in contact with the second source/drain pattern; a front wiring line on the first source/drain pattern and the second source/drain pattern, and connected to the second source/drain pattern; and a front source/drain contact between the front wiring line and the second source/drain pattern. At least one of the first source/drain pattern and the second source/drain pattern includes a semiconductor liner film, and a semiconductor filling film on the semiconductor liner film. The semiconductor liner film includes an outer side face that is in contact with the channel pattern, and an inner side face that is in contact with the semiconductor filling film. The semiconductor filling film fills a liner recess defined by the inner side face of the semiconductor liner film. The back contact silicide film is in contact with the semiconductor liner film of the first source/drain pattern, and is not in contact with the semiconductor filling film of the first source/drain pattern.

According to another aspect of an embodiment, a semiconductor device includes: a back interlayer insulating film; a back wiring line inside the back interlayer insulating film, wherein the back wiring line includes a first side and a second side opposite the first side along a first direction; a first source/drain pattern on the first side of the back wiring line; a second source/drain pattern on the first side of the back wiring line, and spaced apart from the first source/drain pattern along a second direction; a channel pattern between the first source/drain pattern and the second source/drain pattern, and connected to the first source/drain pattern and the second source/drain pattern; a back source/drain contact between the first source/drain pattern and the back wiring line, and connected to the first source/drain pattern, wherein the back source/drain contact overlaps the first source/drain pattern along the first direction; a sacrificial semiconductor pattern between the second source/drain pattern and the back wiring line, and in contact with the second source/drain pattern; a front wiring line on the first source/drain pattern and the second source/drain pattern, and connected to the second source/drain pattern; and a front source/drain contact between the front wiring line and the second source/drain pattern. The sacrificial semiconductor pattern includes a contact side that is in contact with the second source/drain pattern. A height from the first side of the back wiring line to an uppermost portion of the contact side of the sacrificial semiconductor pattern is greater than a height from the first side of the back wiring line to a lowermost portion of the second source/drain pattern. The height from the first side of the back wiring line to the uppermost portion of the contact side of the sacrificial semiconductor pattern is equal to or greater than a height from the first side of the back wiring line to an uppermost portion of the back source/drain contact. The back source/drain contact includes a first side connected to the first source/drain pattern, and a second side which is opposite to the first side of the back source/drain contact along the first direction and connected to the back wiring line. The first side of the back source/drain contact has a concave shape.

According to another aspect of an embodiment, a method of fabricating a semiconductor device, includes: providing a fin-shaped pattern on a substrate, the fin-shaped pattern including a lower pattern, a sacrificial semiconductor film, and an upper pattern; forming a field insulating film on side walls of the find-shaped pattern; forming a dummy gate insulating film, a dummy gate electrode, and a dummy gate capping film on the upper pattern; forming a pre-gate spacer on a side wall of the dummy gate electrode; forming a pre-source/drain recess in the upper pattern by using the dummy gate electrode as a mask; forming a fin spacer on the field insulating film; forming a source/drain recess inside upper pattern that extends into the sacrificial semiconductor film; forming a source/drain pattern in the source/drain recess; removing the dummy gate insulating film and the dummy gate electrode to expose the upper pattern between gate spacers; removing a sacrificial channel pattern to form a gate trench between the gate spacers; forming a gate capping pattern on a gate electrode in the gate trench; forming a front source/drain contact on an upper side of the substrate; forming a front wiring structure on the front source/drain contact; removing the substrate and the lower pattern; forming a sacrificial filling film in an area previously occupied by the lower pattern; forming an active region insulating pattern to separate the sacrificial filling film into portions; forming a back mask pattern on the active region insulating pattern and the sacrificial filling film; forming a back contact hole that exposes the source/drain pattern; and forming a back contact in the back contact hole.

The upper pattern may include a plurality of sacrificial channel patterns and a plurality of active patterns that are stacked alternately on the sacrificial semiconductor film.

The forming the source/drain pattern may include forming a semiconductor liner film along the source/drain recess; and forming the semiconductor filling film on the semiconductor liner film to fill a liner recess.

The semiconductor liner film may be doped with p-type impurities.

The method may further include doping the semiconductor liner with additional p-type impurities.

The back contact hole may be defined by the active region insulating pattern and the field insulating film.

The sacrificial filling film and the back mask pattern may be removed.

It should be noted that the effects of the present disclosure are not limited to those described above, and other effects of the present disclosure will be apparent from the following description.

### BRIEF DESCRIPTION OF DRAWINGS

The above and other aspects and features will be more apparent from the following description of embodiments, taken in conjunction with the attached drawings, in which:

FIG. 1 is an example layout diagram for explaining a semiconductor device according to some embodiments.

FIGS. 2 to 7 are cross-sectional views for explaining a semiconductor device according to some embodiments.

FIG. 8 is a diagram for explaining a fraction of germanium and a concentration of p-type impurities depending on the positions of a semiconductor liner film of FIG. 2.

FIGS. 9 and 10 are diagrams for explaining a semiconductor device according to some embodiments.

FIG. 11 is a diagram for explaining a semiconductor device according to some embodiments.

FIG. 12 is a diagram for explaining a semiconductor device according to some embodiments.

FIGS. 13 to 17 are diagrams for explaining a semiconductor device according to some embodiments.

FIGS. 18 to 35 are intermediate stage diagrams for explaining a method for fabricating a semiconductor device according to some embodiments.

FIGS. 36 to 65 are intermediate stage diagrams for explaining a method for fabricating a semiconductor device according to some embodiments.

### DETAILED DESCRIPTION

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. Although the first, second, and the like are used herein to describe various elements or components, it is obvious that these elements or components are not limited by these terms. These terms are merely used to distinguish one element or component from another element or component. Accordingly, it is obvious that the first element or component as mentioned below may be the second element or component within the technical idea of the present disclosure.

Although drawings of a semiconductor device according to some embodiments show a fin-shaped transistor (FinFET) including a channel region of a fin-shaped pattern shape, a transistor including a nanowire or a nanosheet, and a MBCFET™ (Multi-Bridge Channel Field Effect Transistor) as an example, embodiments are not limited thereto. The semiconductor device according to some embodiments may, of course, include a tunneling transistor (tunneling FET) or a three-dimensional (3D) transistor. The semiconductor device according to some embodiments may, of course, include a planar transistor. In addition, the technical idea of the present disclosure may be applied to a transistor based on two-dimensional material (2D material based FETs) and a heterostructure thereof.

Further, the semiconductor device according to some embodiments may also include a bipolar junction transistor, a laterally diffused metal oxide semiconductor (LDMOS), or the like.

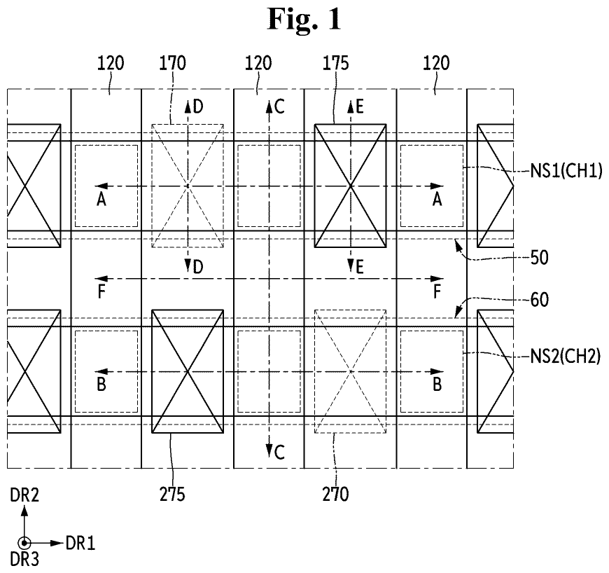

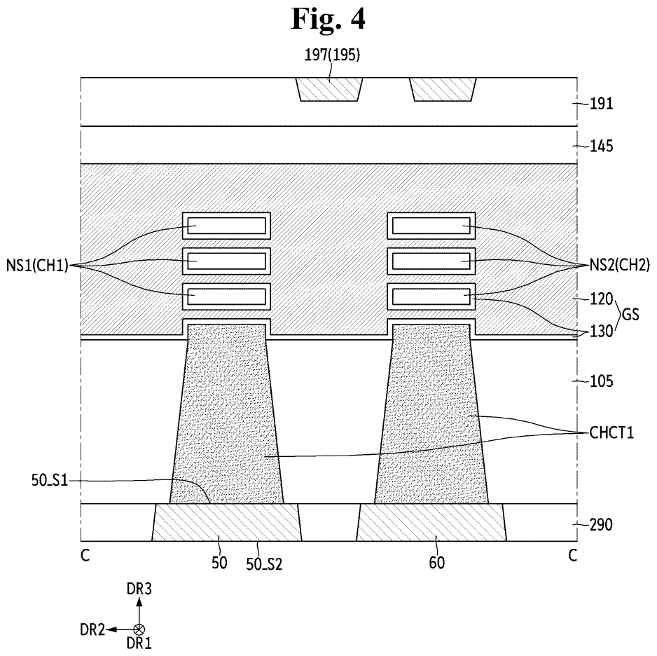

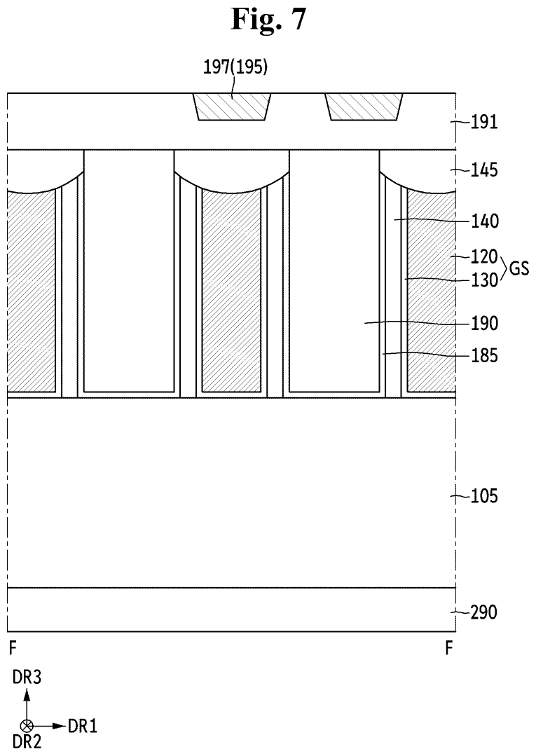

The semiconductor device according to some embodiments will be described referring to FIGS. 1 to 8.

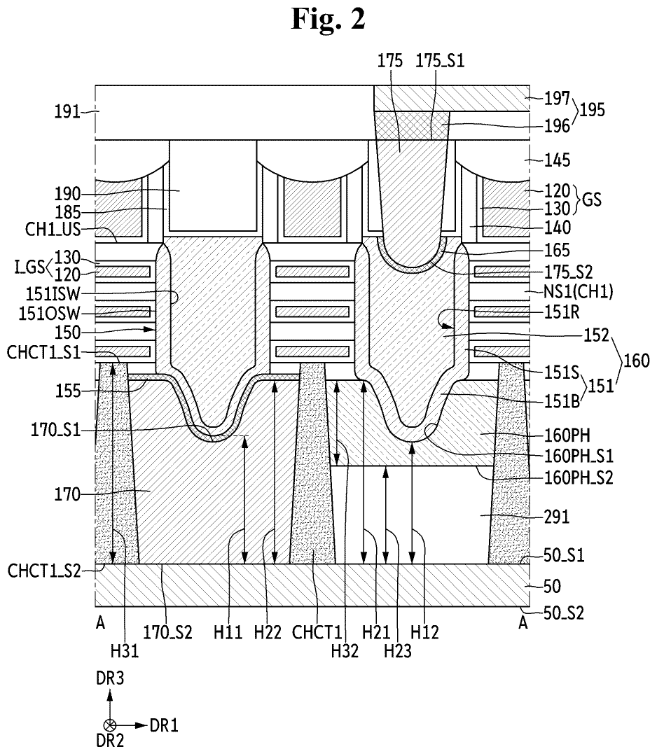

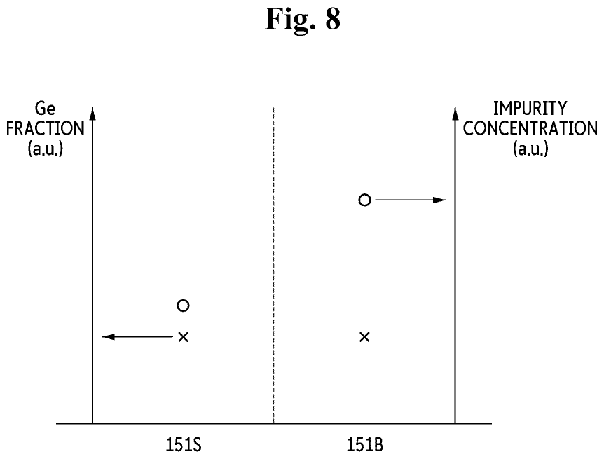

FIG. 1 is an example layout diagram for explaining the semiconductor device according to some embodiments. FIGS. 2 to 7 are cross-sectional views taken along lines A-A, B-B, C-C, D-D, E-E, and F-F of FIG. 1, respectively. FIG. 8 is a diagram for explaining a fraction of germanium and a concentration of p-type impurities depending on the positions of a semiconductor liner film of FIG. 2. For convenience of explanation, a front wiring structure 195 is not shown in FIG. 1.

Referring to FIGS. 1 to 8, the semiconductor device according to some embodiments may include a first channel pattern CH1, a second channel pattern CH2, a plurality of gate electrodes 120, a first source/drain pattern 150, a second source/drain pattern 160, a third source/drain pattern 250, a fourth source/drain pattern 260, a first back source/drain contact 170, a second back source/drain contact 270, a first front source/drain contact 175, a second front source/drain contact 275, a first back wiring line 50, a second back wiring line 60, a front wiring structure 195, a first sacrificial semiconductor pattern 160PH, a second sacrificial semiconductor pattern 260PH, and a first active region insulating pattern CHCT1.

The first back wiring line 50 and the second back wiring line 60 may be disposed inside the back interlayer insulating film 290. Each of the first back wiring line 50 and the second back wiring line 60 may extend in a first direction DR1. The first back wiring line 50 may be spaced apart from the second back wiring line 60 in a second direction DR2.

As an example, the first back wiring line 50 and the second back wiring line 60 may be power lines that supply power to the semiconductor device. As another example, the first back wiring line 50 and the second back wiring line 60 may be signal lines that supply operation signals of the semiconductor device. As yet another example, one of the first back wiring line 50 and the second back wiring line 60 may be a power line, and the other may be a signal line.

The first back wiring line 50 may include a first side 50_S1 and a second side 50_S2 that are opposite to each other in a third direction DR3. The second back wiring line 60 may include a first side and a second side that are opposite to each other in the third direction DR3. A first side 50_S1 of the first back wiring line and the first side of the second back wiring line 60 may face the first channel pattern CH1 and the second channel pattern CH2. Here, the first direction DR1 and the second direction DR2 may be perpendicular to the third direction DR3. Also, the first direction DR1 may be perpendicular to the second direction DR2.

The first back wiring line 50 and the second back wiring line 60 are shown to have a trapezoidal cross section, but embodiments are not limited thereto. For example, the first back wiring line 50 and the second back wiring line 60 may have a rectangular cross section. Taking the first back wiring line 50 as an example, a width of the first side 50_S1 of the first back wiring line in the second direction DR2 may be less than a width of a second side 50_S2 of the first back wiring line in the second direction DR2.

For example, the first back wiring line 50 and the second back wiring line 60 may be formed, using a damascene process. After a trench extending in the first direction DR1 is formed in the back interlayer insulating film 290, the first back wiring line 50 and the second back wiring line 60 may be formed by filling the trench with a conductive material.

The first back wiring line 50 and the second back wiring line 60 are shown as having a single conductive film structure, but embodiments are not limited thereto. For example, the first back wiring line 50 and the second back wiring line 60 may have multiple conductive film structures including a back wiring barrier film and a back wiring filling film. In such a case, the back wiring filling film may fill the wiring filling film trench defined by the back wiring barrier film.

The first back wiring line 50 and the second back wiring line 60 may include at least one of, for example, a metal, a conductive metal nitride, a conductive metal carbide, a conductive metal oxide, a conductive metal oxynitride, a conductive metal carbonitride, or a two-dimensional material. The two-dimensional material (2D material) may include a two-dimensional allotrope or a two-dimensional compound, and may include, for example, but is not limited to, at least one of graphene, boron nitride (BN), molybdenum sulfide, molybdenum selenide, tungsten sulfide, tungsten selenide, and tantalum sulfide. That is, because the above-mentioned 2D materials are listed examples, the 2D materials that may be included in the semiconductor device are not limited by the above-mentioned materials.

For example, each of the first back wiring line 50 and the second back wiring line 60 may extend in the second direction DR2. In such a case, the shapes of the cross-sectional views taken along A-A, B-B, C-C, D-D, E-E, and F-F of FIG. 1 may vary.

In some embodiments, each of the first back wiring line 50 and the second back wiring line 60 may include a line portion and a via portion. Taking the first back wiring line 50 as an example, the line portion of the first back wiring line 50 may extend long in the first direction DR1. The via portion of the first back wiring line 50 may protrude from the line portion of the first back wiring line 50 in the third direction DR3. The via portion of the first back wiring line 50 may protrude toward the first back source/drain contact 170.

The back interlayer insulating film 290 may include at least one of, for example, silicon oxide, silicon nitride, silicon oxycarbide, silicon oxynitride, or a low dielectric constant material (i.e., a low-κ material). The dielectric constant of the low dielectric constant material may have a value less than 3.9, which is the dielectric constant of silicon oxide. Although the back interlayer insulating film 290 is shown to be a single film, this is only for convenience of explanation, and embodiments are not limited thereto. The back interlayer insulating film 290 may include a plurality of films.

The first back interlayer insulating film 291 may be disposed on the back interlayer insulating film 290. The first back interlayer insulating film 291 may be disposed on the first side 50_S1 of the first back wiring line and the first side of the second back wiring line 60.

The first back interlayer insulating film 291 may be disposed between the first back wiring line 50 and the second source/drain pattern 160, and between the second back wiring line 60 and the fourth source/drain pattern 260.

The first back insertion insulating film 291 may include at least one of, for example, silicon nitride, silicon oxynitride, silicon oxide, silicon oxycarbonitride, silicon boronitride, silicon oxyboronitride, silicon carbonitride, silicon oxycarbide, or a low dielectric constant material (i.e., a low-κ material). As an example, the first back insertion insulating film 291 may include silicon oxide.

The first sacrificial semiconductor pattern 160PH and the second sacrificial semiconductor pattern 260PH may be disposed on the first back insertion insulating film 291. The first sacrificial semiconductor pattern 160PH may be disposed between the first back wiring line 50 and the second source/drain pattern 160. The second sacrificial semiconductor pattern 260PH may be disposed between the second back wiring line 60 and the fourth source/drain pattern 260.

More specifically, the first sacrificial semiconductor pattern 160PH may be disposed between the first back insertion insulating film 291 and the second source/drain pattern 160. The second sacrificial semiconductor pattern 260PH may be disposed between the first back insertion insulating film 291 and the fourth source/drain pattern 260.

The first sacrificial semiconductor pattern 160PH may include a contact side 160PH_S1 that is in contact with the second source/drain pattern 160, and a bottom side 160PH_S2 that faces the first back wiring line 50. The first sacrificial semiconductor pattern 160PH may include a side wall that connects the contact side 160PH_S1 of the first sacrificial semiconductor pattern and the bottom side 160PH_S2 of the first sacrificial semiconductor pattern.

The second sacrificial semiconductor pattern 260PH may include a contact side that is in contact with the fourth source/drain pattern 260, and a bottom side that faces the second back wiring line 60. The second sacrificial semiconductor pattern 260PH may include a side wall that connects the contact side of the second sacrificial semiconductor pattern 260PH and the bottom side of the second sacrificial semiconductor pattern 260PH.

The first sacrificial semiconductor pattern 160PH and the second sacrificial semiconductor pattern 260PH may include, for example, silicon-germanium.

A field insulating film 105 may be disposed on the first back wiring line 50 and the second back wiring line 60. For example, the field insulating film 105 may be disposed on the first side 50_S1 of the first back wiring line and the first side of the second back wiring line 60.

The first back insertion insulating film 291 may include an upper side and a bottom side opposite to each other in the third direction DR3, and a side wall that connects the upper side of the first back insertion insulating film 291 and the bottom side of the first back insertion insulating film 291. The field insulating film 105 may be disposed on the side wall of the first back insertion insulating film 291, the side wall of the first sacrificial semiconductor pattern 160PH, and the side wall of the second sacrificial semiconductor pattern 260PH. The field insulating film 105 may be on (and for example may cover) the side wall of the first back insertion insulating film 291, the side wall of the first sacrificial semiconductor pattern 160PH, and the side wall of the second sacrificial semiconductor pattern 260PH.

The field insulating film 105 may include, for example, at least one of silicon oxide, silicon nitride, silicon oxynitride, and a low dielectric constant material (i.e., a low-κ material). Although the field insulating film 105 is shown as being a single film, this is only for convenience of explanation and embodiments are not limited thereto. The field insulating film 105 may include a plurality of films.

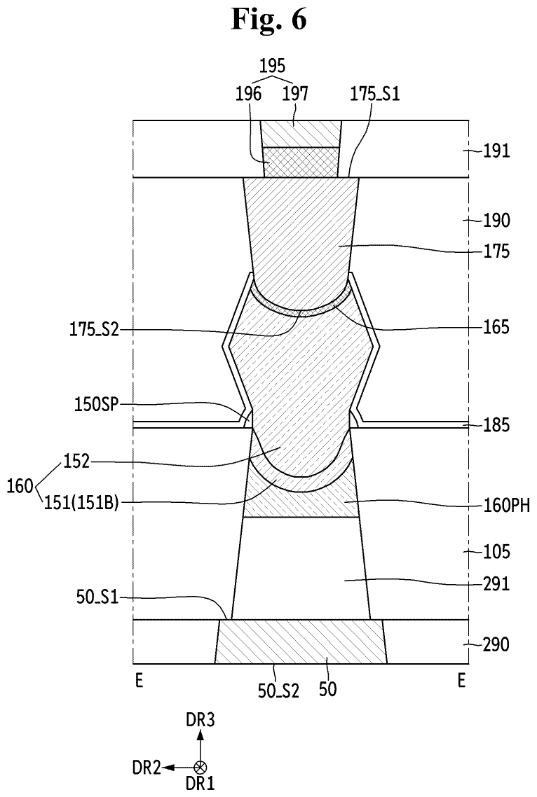

When the first back insertion insulating film 291 and the field insulating film 105 include the same insulating material, a boundary between the first back insertion insulating film 291 and the field insulating film 105 may not be distinguished in a cross-sectional view such as FIG. 6. In such a case, the portion that overlaps the first sacrificial semiconductor pattern 160PH in the third direction DR3 may be the first back insertion insulating film 291.

The first channel pattern CH1 and the second channel pattern CH2 may be disposed on the first side 50_S1 of the first back wiring line and the first side of the second back wiring line 60. The first side 50_S1 of the first back wiring line and the first side of the second back wiring line 60 may face the first channel pattern CH1 and the second channel pattern CH2.

The first channel pattern CH1 may be disposed on the first sacrificial semiconductor pattern 160PH. The first channel pattern CH1 may be in contact with the first sacrificial semiconductor pattern 160PH. The second channel pattern CH2 may be disposed on the second sacrificial semiconductor pattern 260PH. The second channel pattern CH2 may be in contact with the second sacrificial semiconductor pattern 260PH.

The first channel pattern CH1 and the second channel pattern CH2 may be spaced apart from each other in the second direction DR2. The first channel pattern CH1 and the second channel pattern CH2 may be adjacent to each other in the second direction DR2. For example, the first channel pattern CH1 may be a region in which a p-type transistor is formed, and the second channel pattern CH2 may be a region in which an n-type transistor is formed.

Each of the first channel pattern CH1 and the second channel pattern CH2 may be a multi-channel active pattern. In the semiconductor device according to some embodiments, the first channel pattern CH1 may include a plurality of first sheet patterns NS1, and the second channel pattern CH2 may include a plurality of second sheet patterns NS2. In the semiconductor device according to some embodiments, each of the first and second channel patterns CH1, CH2 may be an active pattern including a nanosheet or a nanowire.

The plurality of first sheet patterns NS1 may be disposed on the first sacrificial semiconductor pattern 160PH. The plurality of first sheet patterns NS1 may be spaced apart from the first sacrificial semiconductor pattern 160PH in the third direction DR3. Each first sheet pattern NS1 may include an upper side and a bottom side that are opposite to each other in the third direction DR3. The bottom side of the first sheet pattern NS1 may face the first sacrificial semiconductor pattern 160PH. The first sheet pattern NS1 may include a first end and a second end. The first end of the first sheet pattern NS1 may be spaced apart from the second end of the first sheet pattern NS1 in the first direction DR1. Each of the first end of the first sheet pattern NS1 and the second end of the first sheet pattern NS1 may be portions connected to the first and second source/drain patterns 150 and 160, which will be described below.

The plurality of first sheet patterns NS1 may include a first lowermost sheet pattern closest to the first back wiring line 50. In the semiconductor device according to some embodiments, the first lowermost sheet pattern may be in contact with the first sacrificial semiconductor pattern 160PH. The bottom side of the first lowermost sheet pattern may be in contact with the first sacrificial semiconductor pattern 160PH. The upper side of the first sheet pattern NS1 farthest from the first back wiring line 50 among the plurality of first sheet patterns NS1 may be an upper side CH1_US of the first channel pattern.

The plurality of second sheet patterns NS2 may be disposed on the second sacrificial semiconductor pattern 260PH. The plurality of second sheet patterns NS2 may be spaced apart from the second sacrificial semiconductor pattern 260PH in the third direction DR3. Each second sheet pattern NS2 may include an upper side and a bottom side opposite to each other in the third direction DR3. The bottom side of the second sheet pattern NS2 may face the second sacrificial semiconductor pattern 260PH. The second sheet pattern NS2 may include a first end and a second end. The first end of the second sheet pattern NS2 may be spaced apart from the second end of the second sheet pattern NS2 in the first direction DR2. Each of the first end of the second sheet pattern NS2 and the second end of the second sheet pattern NS2 may be portions connected to third and fourth source/drain patterns 250 and 260, which will be described below.

The plurality of second sheet patterns NS2 may include a second lowermost sheet pattern that is in contact with the second sacrificial semiconductor pattern 260PH. The upper side of the second sheet pattern NS2 farthest from the second back wiring line 60 among the plurality of second sheet patterns NS2 may be an upper side CH2_US of the second channel pattern.

Although the four first sheet patterns NS1 and the four second sheet patterns NS2 are shown as being disposed in the third direction DR3, respectively, this is only for convenience of explanation, and embodiments are not limited thereto. For example, the first lowermost sheet pattern and the second lowermost sheet pattern may be dummy sheet patterns that are not used as a channel region of a transistor.

Each of the first sheet pattern NS1 and the second sheet pattern NS2 may include silicon or germanium, which are elemental semiconductor materials. In addition, each of the first sheet pattern NS1 and the second sheet pattern NS2 may include a compound semiconductor, and may include, for example, a group IV-IV compound semiconductor or a group III-V compound semiconductor.

The group IV-IV compound semiconductor may be, for example, a binary compound, a ternary compound including at least two of carbon (C), silicon (Si), germanium (Ge) or tin (Sn), or a compound obtained by doping these elements with a group IV element.

The group III-V compound semiconductor may be, for example, one of a binary compound, a ternary compound, or a quaternary compound formed by combining at least one of aluminum (Al), gallium (Ga) or indium (In), which is a group III element, with one of phosphorus (P), arsenic (As) or antimonium (Sb), which is a group V element.

Although widths of each first sheet pattern NS1 are shown to be the same, embodiments are not limited thereto. Although the widths of each second sheet pattern NS2 are shown to be the same, embodiments are not limited thereto.

The plurality of gate structures GS may be disposed on the first side 50_S1 of the first back wiring line and the first side of the second back wiring line 60. The plurality of gate structures GS may be disposed on the field insulating film 105.

The first sacrificial semiconductor pattern 160PH may be disposed between the gate structure GS and the first back wiring line 50. The second sacrificial semiconductor pattern 260PH may be disposed between the gate structure GS and the second back wiring line 60.

Each gate structure GS may extend in the second direction DR2. The gate structures GS may be disposed to be spaced apart in the first direction DR1. The gate structures GS may be adjacent to each other in the first direction DR1.

The gate structure GS may enclose the first sheet pattern NS1. The gate structure GS may enclose the second sheet pattern NS2. The gate structure GS may not enclose the first lowermost sheet pattern and the second lowermost sheet pattern.

Although the gate structure GS is show as being disposed over the first channel pattern CH1 and the second channel pattern CH2, this is only for convenience of explanation, and embodiments are not limited thereto. That is, a portion of the gate structure GS may be separated into a first portion and a second portion by a gate separation structure disposed on the field insulating film 105. In such a case, the first portion of the gate structure GS may enclose the first sheet pattern NS1, and the second portion of the gate structure GS may enclose the second sheet pattern NS2.

The gate structure GS may include, for example, a gate electrode 120 and a gate insulating film 130.

In the semiconductor device according to some embodiments, the gate structure GS may include a plurality of inner gate structures I_GS disposed between the first sheet patterns NS1 adjacent to each other in the third direction DR3. The inner gate structure I_GS may be disposed between the second sheet patterns NS2 adjacent to each other in the third direction DR3.

The inner gate structure I_GS may be disposed between the upper side of the first sheet pattern NS1 and the bottom side of the first sheet pattern NS1 that face each other in the third direction DR3. The inner gate structure I_GS may be disposed between the upper side of the second sheet pattern NS2 and the bottom side of the second sheet pattern NS2 that face each other in the third direction DR3. The inner gate structure I_GS may include a gate electrode 120 and a gate insulating film 130.

The inner gate structure I_GS may be in contact with the upper side of the first sheet pattern NS1 and the bottom side of the first sheet pattern NS1. The inner gate structure I_GS may be in contact with the upper side of the second sheet pattern NS2 and the bottom side of the second sheet pattern NS2.

In the semiconductor device according to some embodiments, the inner gate structure I_GS may be in contact with the first and second source/drain patterns 150 and 160 to be described below. The inner gate structure I_GS may be in contact with the third and fourth source/drain patterns 250 and 260 to be described below.

The gate electrode 120 may be disposed on the first sacrificial semiconductor pattern 160PH and the second sacrificial semiconductor pattern 260PH. The gate electrode 120 may enclose the first sheet pattern NS1 and the second sheet pattern NS2.

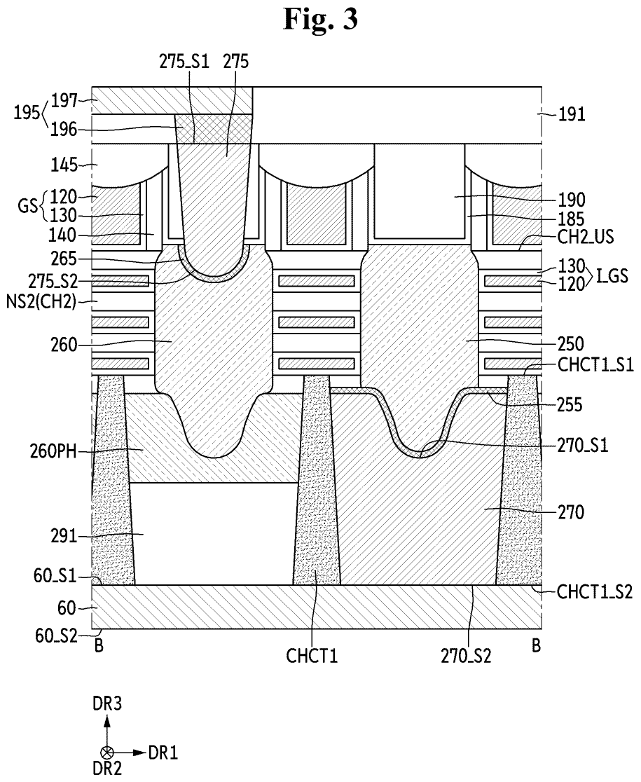

In the cross-sectional views such as FIGS. 2 and 3, the upper side of the gate electrode 120 is shown as having a concave curved face, but embodiments are not limited thereto. For example, the upper side of the gate electrode 120 may be planar.

The gate electrode 120 may include at least one of a metal, a conductive metal nitride, a metal silicide, a doped semiconductor material, a conductive metal oxide, a conductive metal oxynitride, a conductive metal carbide or a conductive metal carbonitride. The gate electrode 120 may include, for example, but is not limited to at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V) or combinations thereof. The conductive metal oxide and the conductive metal oxynitride may include, but are not limited to, an oxidized form of the aforementioned materials.

The gate insulating film 130 may extend along an upper side of the field insulating film 105. The gate insulating film 130 may enclose the first sheet pattern NS1. The gate insulating film 130 may enclose the second sheet pattern NS2. The gate insulating film 130 may be disposed along a periphery of the first sheet pattern NS1 and a periphery of the second sheet pattern NS2. The gate electrode 120 may be disposed on the gate insulating film 130.

The gate insulating film 130 may be disposed between the gate electrode 120 and the first sheet pattern NS1, and between the gate electrode 120 and the second sheet pattern NS2. In the semiconductor device according to some embodiments, the gate insulating film 130 included in the inner gate structure I_GS may be in contact with first to fourth source/drain patterns 150, 160, 250, and 260 to be described below.

The gate insulating film 130 may include silicon oxide, silicon oxynitride, silicon nitride or a high dielectric constant material (i.e., a high-κ material) having a dielectric constant higher than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as being a single film, this is only for convenience of explanation, and embodiments are not limited thereto. The gate insulating film 130 may include a plurality of films. The gate insulating film 130 may include an interfacial film disposed between the first sheet pattern NS1 and the gate electrode 120, and between the second sheet pattern NS2 and the gate electrode 120, and a high dielectric constant insulating film (i.e., a high-κ film). For example, the interfacial film may not be formed along the profile of the upper side of the field insulating film 105.

A semiconductor device according to some embodiments may include an NC (Negative Capacitance) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide or lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at % (atomic %) aluminum. Here, a ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have paraelectric properties. The paraelectric material film may include at least one of, for example, a silicon oxide or a metal oxide having a high dielectric constant (i.e., greater than 3.9). The metal oxide included in the paraelectric material film may include, for example, but is not limited to, at least one of hafnium oxide, zirconium oxide, or aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, but is not limited to, 0.5 to 10 nm. Because a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the side wall of the gate electrode 120. In the semiconductor device according to some embodiments, the gate spacer 140 may not be disposed between the first sheet patterns NS1 adjacent to each other in the third direction D3. The gate spacer 140 may not be disposed between the second sheet patterns NS2 adjacent to each other in the third direction D3

The gate spacer 140 may include, for example, at least one of silicon nitride, silicon oxynitride, silicon oxide, silicon oxycarbonitride, silicon boronitride, silicon oxyboronitride, silicon oxycarbide or combinations thereof. Although the gate spacer 140 is shown to be a single film, this example is only for convenience of explanation and is not limited thereto. The gate spacer 140 may include a plurality of films.

A gate capping pattern 145 may be disposed on the gate electrode 120. The upper face of the gate capping pattern 145 may be placed on the same plane as the upper side of the first interlayer insulating film 190. In some embodiments, the gate capping pattern 145 may be disposed between the gate spacers 140.

The gate capping pattern 145 may include, for example, at least one of silicon nitride, silicon oxynitride, silicon carbonitride, silicon oxycarbonitride, and combinations thereof. The gate capping pattern 145 may include a material having an etching selectivity with respect to the first interlayer insulating film 190.

The first active region insulating pattern CHCT1 may be disposed on the first side 50_S1 of the first back wiring line and the first side of the second back wiring line 60. The first active region insulating pattern CHCT1 may be disposed between the first channel pattern CH1 and the first back wiring line 50. The first active region insulating pattern CHCT1 may be disposed between the second channel pattern CH2 and the second back wiring line 60.

The first active region insulating pattern CHCT1 may extend in the third direction DR3. The first active region insulating pattern CHCT1 may overlap the gate structure GS in the third direction DR3.

The first active region insulating pattern CHCT1 may be in contact with the first channel pattern CH1. The first active region insulating pattern CHCT1 may penetrate a first lowermost sheet pattern among the plurality of first sheet patterns NS1. The first active region insulating pattern CHCT1 may be in contact with the second channel pattern CH2. The first active region insulating pattern CHCT1 may penetrate a second lowermost sheet pattern among the plurality of second sheet patterns NS2.

The first active region insulating pattern CHCT1 may include a first side CHCT1_S1 and a second side CHCT1_S2 that are opposite to each other in the third direction DR3. The second side CHCT1_S2 of the first active region insulating pattern may face the first back wiring line 50 and the second back wiring line 60. In FIGS. 2 and 3, the first active region insulating pattern CHCT1 may be in contact with the inner gate structure I_GS. For example, the first side CHCT1_S1 of the first active region insulating pattern may be in contact with the inner gate structure I_GS.

The field insulating film 105 may be on (and for example may cover) a side wall of the first active region insulating pattern CHCT1. The width of the second side CHCT1_S2 of the first active region insulating pattern in the first direction DR1 may be greater than the width of the first side CHCT1_S1 of the first active region insulating pattern in the first direction DR1. The width of the first active region insulating pattern CHCT1 in the first direction DR1 may decrease as it goes away from the first side 50_S1 of the first back wiring line or the first side of the second back wiring line 60.

The first sacrificial semiconductor pattern 160PH and the first back insertion insulating film 291 may be disposed between the first active region insulating patterns CHCT1 adjacent to each other in the first direction DR1. The second sacrificial semiconductor pattern 260PH and the first back insertion insulating film 291 may be disposed between the first active region insulating patterns CHCT1 adjacent to each other in the first direction DR1.

The first active region insulating pattern CHCT1 may include an insulating material. The first active region insulating pattern CHCT1 may include at least one of, for example, silicon nitride, silicon oxynitride, silicon oxide, silicon oxycarbonitride, silicon boronitride, silicon oxyboronitride, silicon carbonitride or silicon oxycarbide. As an example, the first active region insulating pattern CHCT1 may include silicon nitride.

The first source/drain pattern 150 and the second source/drain pattern 160 may be disposed on a first side 50_S1 of the first back wiring line. The second source/drain pattern 160 may be spaced apart from the first source/drain pattern 150 in the first direction DR1.

The first source/drain pattern 150 and the second source/drain pattern 160 may be connected to the first channel pattern CH1. The first source/drain pattern 150 and the second source/drain pattern 160 may be in contact with the first sheet pattern NS1. The first source/drain pattern 150 may be connected to a first end of the first sheet pattern NS1. The second source/drain pattern 160 may be connected to a second end of the first sheet pattern NS1.

The first channel pattern CH1 may be disposed between the first source/drain pattern 150 and the second source/drain pattern 160. The gate electrode 120 may be disposed between the first source/drain pattern 150 and the second source/drain pattern 160.

The second source/drain pattern 160 may be disposed on the first sacrificial semiconductor pattern 160PH. The second source/drain pattern 160 may overlap the first sacrificial semiconductor pattern 160PH in the third direction DR3.

The third source/drain pattern 250 and the fourth source/drain pattern 260 may be disposed on the first side of the second back wiring line 60. The fourth source/drain pattern 260 may be spaced apart from the third source/drain pattern 250 in the first direction DR1.

The third source/drain pattern 250 and the fourth source/drain pattern 260 may be connected to the second channel pattern CH2. The third source/drain pattern 250 and the fourth source/drain pattern 260 may be in contact with the second sheet pattern NS2. The third source/drain pattern 250 may be connected to a first end of the second sheet pattern NS2. The fourth source/drain pattern 260 may be connected to a second end of the second sheet pattern NS2. The second channel pattern CH2 may be disposed between the third source/drain pattern 250 and the fourth source/drain pattern 260.

The fourth source/drain pattern 260 may be disposed on the second sacrificial semiconductor pattern 260PH. The fourth source/drain pattern 260 may overlap the second sacrificial semiconductor pattern 260PH in the third direction DR3.

The first source/drain pattern 150 and the second source/drain pattern 160 may be included in the source/drain of a transistor that uses the first channel pattern CH1 as a channel region. The third source/drain pattern 250 and the fourth source/drain pattern 260 may be included in the source/drain of a transistor that uses the second channel pattern CH2 as a channel region.

Each of the first to fourth source/drain patterns 150, 160, 250, and 260 may include an epitaxial pattern. Each of the first to fourth source/drain patterns 150, 160, 250, and 260 may include a semiconductor material.

Each of the first source/drain pattern 150 and the second source/drain pattern 160 may include a semiconductor liner film 151 and a semiconductor filling film 152.

The semiconductor liner film 151 may be in contact with the first channel pattern CH1. The semiconductor liner film 151 may extend up to the upper side CH1_US of the first channel pattern.

The semiconductor liner film 151 may include an outer side face 151OSW and an inner side face 151ISW. The outer side face 151OSW of the semiconductor liner film may be in contact with the first channel pattern CH1. In the semiconductor device according to some embodiments, the outer side face 151OSW of the semiconductor liner film may be in contact with the inner gate structure I/GS.

The inner side face 151ISW of the semiconductor liner film may be a face opposite to the outer side face 151OSW of the semiconductor liner film. The inner side face 151ISW of the semiconductor liner film may be a face that faces the semiconductor filling film 152. For example, the inner side face 151ISW of the semiconductor liner film may be in contact with the semiconductor filling film 152.

The semiconductor liner film 151 may define a liner recess 151R. For example, the liner recess 151R may be defined by the inner side face 151ISW of the semiconductor liner film.

The semiconductor liner film 151 may include a bottom portion 151B and a side wall portion 151S. The bottom portion 151B of the semiconductor liner film may be in direct contact with the side wall portion 151S of the semiconductor liner film.

The side wall portion 151S of the semiconductor liner film may be in contact with the first channel pattern CH1. The side wall portion 151S of the semiconductor liner film may extend in the third direction DR3. The side wall portion 151S of the semiconductor liner film may extend up to the upper side CH1_US of the first channel pattern.

The semiconductor liner film 151 of the first source/drain pattern 150 may be in contact with the first back contact silicide film 155. For example, in the first source/drain pattern 150, the bottom portion 151B of the semiconductor liner film may be in contact with the first back contact silicide film 155.

The semiconductor liner film 151 of the second source/drain pattern 160 may be in contact with the first sacrificial semiconductor pattern 160PH. In the second source/drain pattern 160, the bottom portion 151B of the semiconductor liner film may be in contact with the first sacrificial semiconductor pattern 160PH.

In a cross-sectional view such as FIG. 2, the side wall portion 151S of the semiconductor liner film may be located above an interface between the first channel pattern CH1 and the first sacrificial semiconductor pattern 160PH. The bottom portion 151B of the semiconductor liner film may be located below the interface between the first channel pattern CH1 and the first sacrificial semiconductor pattern 160PH.

The semiconductor filling film 152 may be disposed on the semiconductor liner film 151. The semiconductor filling film 152 may fill the liner recess 151R. Although the semiconductor filling film 152 is shown to be a single film, this is only for convenience of explanation, and embodiments are not limited thereto. The semiconductor filling film 152 may include a plurality of films.

Each of the semiconductor liner film 151 and the semiconductor filling film 152 may include silicon-germanium. The fraction of germanium of the semiconductor filling film 152 may be greater than the fraction of germanium of the semiconductor liner film 151. The fraction of germanium of the first sacrificial semiconductor pattern 160PH may be greater than the fraction of germanium of the semiconductor liner film 151. Due to the difference in germanium fraction, the first sacrificial semiconductor pattern 160PH may have an etching selectivity with respect to the semiconductor liner film 151.

The first source/drain pattern 150 and the second source/drain pattern 160 may include p-type impurities. The p-type impurities may include, but are not limited to, at least one of boron (B) or gallium (Ga).

In FIG. 8, the fraction of germanium of the bottom portion 151B of the semiconductor liner film may be equal to the fraction of germanium of the side wall portion 151S of the semiconductor liner film. The concentration (/cm³) of the p-type impurities included in the bottom portion 151B of the semiconductor liner film may be higher than the concentration of the p-type impurities included in the side wall portion 151S of the semiconductor liner film. The comparison of concentrations of the p-type impurity between the bottom portion 151B of the semiconductor liner film and the side wall portion 151S of the semiconductor liner film may be a comparison of average concentrations rather than a comparison of concentrations at specific points.

Each of the third source/drain pattern 250 and the fourth source/drain pattern 260 may include silicon. The third source/drain pattern 250 and the fourth source/drain pattern 260 may include n-type impurities. The n-type impurities may include, but are not limited to, at least one of phosphorus (P), arsenic (As), antimony (Sb), or bismuth (Bi).

Although the third source/drain pattern 250 and the fourth source/drain pattern 260 are shown to be single films, embodiments are not limited thereto. The third source/drain pattern 250 and the fourth source/drain pattern 260 may include a plurality of films. That is, as an example, the third source/drain pattern 250 and the fourth source/drain pattern 260 may include silicon films including different n-type impurities from each other. As another example, the third source/drain pattern 250 and the fourth source/drain pattern 260 may include silicon films including different concentrations of n-type impurities. As yet another example, the third source/drain pattern 250 and the fourth source/drain pattern 260 may include silicon films containing different n-type impurities and different concentrations of n-type impurities.

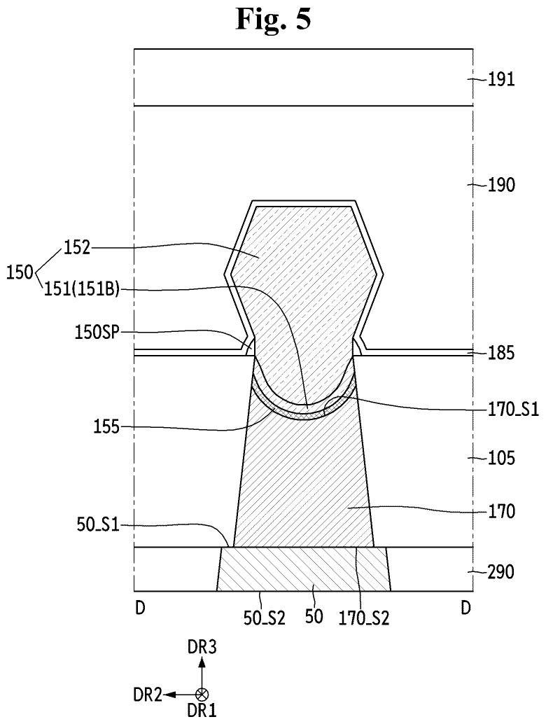

In FIGS. 5 and 6, although an external shape of the first source/drain pattern 150 and an external shape of the second source/drain pattern 160 are shown to be similar to a hexagon, embodiments are not limited thereto. For example, the external shape of the first source/drain pattern 150 and the external shape of the second source/drain pattern 160 may be a shape similar to a pentagon or a quadrangle.

In the semiconductor device according to some embodiments, the first active region insulating pattern CHCT1 may not be in contact with the first source/drain pattern 150 and the second source/drain pattern 160. The first active region insulating pattern CHCT1 may not be in contact with the third source/drain pattern 250 and the fourth source/drain pattern 260.

The first front interlayer insulating film 190 may be disposed on the field insulating film 105. The first front interlayer insulating film 190 may be disposed on the first to fourth source/drain patterns 150, 160, 250, and 260. The first front interlayer insulating film 190 may not cover the upper side of the gate capping pattern 145. For example, the upper side of the first front interlayer insulating film 190 may be disposed in the same plane as the upper side of the gate capping pattern 145.

A fin spacer 150SP may be disposed on the field insulating film 105. The fin spacer 150SP may be disposed on the side wall of the first source/drain pattern 150 and the side wall of the second source/drain pattern 160. The fin spacer 150SP may include an insulating material.

The first front interlayer insulating film 190 may be disposed on the first side 50_S1 of the first back wiring line and the first side of the second back wiring line 60. The first front interlayer insulating film 190 may include, for example, at least one of silicon oxide, silicon nitride, silicon oxynitride, and a low dielectric constant material (i.e., a low-κ material).

A source/drain etching stop film 185 may extend along the profile of the first source/drain pattern 150, the profile of the second source/drain pattern 250, the profile of the third source/drain pattern 250, and the profile of the fourth source/drain pattern 260. The first front interlayer insulating film 190 may be disposed on the source/drain etching stop film 185.

The source/drain etching stop film 185 may include, for example, silicon nitride, silicon oxynitride, silicon oxycarbonitride, silicon boronitride, silicon oxyboronitride, silicon carbonitride or combinations thereof.

The first back source/drain contact 170 may extend long in the third direction DR3. The first back source/drain contact 170 may be connected to the first source/drain pattern 150. For example, the first back source/drain contact 170 may be electrically connected to the first source/drain pattern 150.

The first back source/drain contact 170 may be disposed between the first source/drain pattern 150 and the first back wiring line 50. The first back source/drain contact 170 may overlap the first back wiring line 50 and the first source/drain pattern 150 in the third direction DR3. The first back source/drain contact 170 may be disposed between the first active region insulating patterns CHCT1 adjacent to each other in the first direction DR1.

The first back source/drain contact 170 may connect the first source/drain pattern 150 and the first back wiring line 50. The first back source/drain contact 170 may be connected to the first back wiring line 50. The first back source/drain contact 170 may be connected to the first side 50_S1 of the first back wiring line. The first back source/drain contact 170 may extend from the first side 50_S1 of the first back wiring line to the first source/drain pattern 150.

The first back source/drain contact 170 may include a first side 170_S1 and a second side 170_S2 that are opposite to each other in the third direction DR3. For example, the first side 170_S1 of the first back source/drain contact may be the upper side of the first back source/drain contact 170. The second side 170_S2 of the first back source/drain contact may be the bottom side of the first back source/drain contact 170.

The first side 170_S1 of the first back source/drain contact may face the first source/drain pattern 150. The first side 170_S1 of the first back source/drain contact may be connected to the first source/drain pattern 150. For example, the first side 170_S1 of the first back source/drain contact may be an interface between the first back source/drain contact 170 and the first back contact silicide film 155. The first side 170_S1 of the first back source/drain contact may be a connection side that is in contact with the back contact silicide film 155. The first side 170_S1 of the first back source/drain contact may be a connection side that connects the first back source/drain contact 170 and the first source/drain pattern 150.

The second side 170_S2 of the first back source/drain contact may face the first back wiring line 50. The second side 170_S2 of the first back source/drain contact may be connected to the first back wiring line 50.

The first back contact silicide film 155 may be disposed between the first back source/drain contact 170 and the first source/drain pattern 150. The first back contact silicide film 155 may be in contact with the semiconductor liner film 151 of the first source/drain pattern 150. In the semiconductor device according to some embodiments, the first back contact silicide film 155 may not be in contact with the semiconductor filling film 152 of the first source/drain pattern 150. For example, the first back contact silicide film 155 and the semiconductor filling film 152 of the first source/drain pattern 150 may be spaced apart by the semiconductor liner film 151 of the first source/drain pattern 150.

The lowermost portion of the second source/drain pattern 160 which is not connected to the first back source/drain contact 170 may be closer to the first back wiring line 50 than the lowermost portion of the first source/drain pattern 150 connected to the first back source/drain contact 170. A height H11 from the first side 50_S1 of the first back wiring line to the lowermost portion of the first source/drain pattern 150 may be greater than a height H12 from the first side 50_S1 of the first back wiring line to the lowermost portion of the second source/drain pattern 160.

A portion of the first back source/drain contact 170 may be formed at a position from which the first sacrificial semiconductor pattern 160PH is removed. A height H21 from the first side 50_S1 of the first back wiring line to the uppermost portion of the contact side 160PH_S1 of the first sacrificial semiconductor pattern may be equal to or greater than a height H22 from the first side 50_S1 of the first back wiring line to the uppermost portion of the first back source/drain contact 170.

In the semiconductor device according to some embodiments, a height H31 of the first active region insulating pattern CHCT1 in the third direction DR3 may be greater than a height H32 of the first sacrificial semiconductor pattern 160PH in the third direction DR3.

The height H21 from the first side 50_S1 of the first back wiring line to the uppermost portion of the contact side 160PH_S1 of the first sacrificial semiconductor pattern may be greater than the height H12 from the first side 50_S1 of the first back wiring line to the lowermost portion of the second source/drain pattern 160. In the semiconductor device according to some embodiments, a height H23 from the first side 50_S1 of the first back wiring line to the bottom side 160PH_S2 of the first sacrificial semiconductor pattern may be less than the height H12 from the first side 50_S1 of the first back wiring line to the lowermost portion of the second source/drain pattern 160.

When the first back wiring line 50 does not include a via portion, the height of the first back source/drain contact 170 in the third direction DR3 may be equal to the height H22 from the first side 50_S1 of the first back wiring line to the uppermost portion of the first back source/drain contact 170. In the semiconductor device according to some embodiments, a height H31 of the first active region insulating pattern CHCT1 in the third direction DR3 may be greater than the height H22 of the first back source/drain contact 170 in the third direction DR3.

A first side 170_S1 of the first back source/drain contact may have a concave shape. The first side 170_S1 of the first back source/drain contact may enclose the lower portion of the first source/drain pattern 150. Because the contact resistance between the first back source/drain contact 170 and the first source/drain pattern 150 decreases, the performance and reliability of the semiconductor device may be improved.

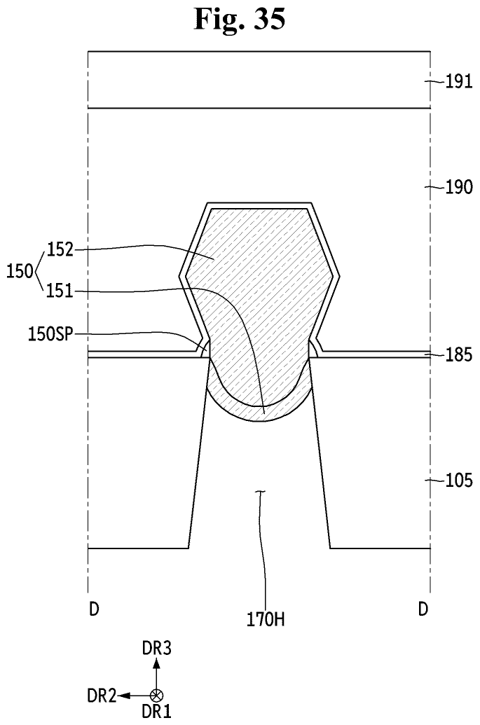

In addition, because a back contact hole (170H of FIG. 35) for forming the first back source/drain contact 170 does not extend into the first source/drain pattern 150, a compressive stress applied by the first source/drain pattern 150 to the first channel pattern CH1 may remain as it is without being relieved. Accordingly, the performance and reliability of the semiconductor device can be improved.

The second back source/drain contact 270 may extend long in the third direction DR3. The second back source/drain contact 270 may be electrically connected to the third source/drain pattern 250.

The second back source/drain contact 270 may be disposed between the third source/drain pattern 250 and the second back wiring line 60. The second back source/drain contact 270 may overlap the second back wiring line 60 and the third source/drain pattern 250 in the third direction DR3. The second back source/drain contact 270 may be disposed between the first active region insulating patterns CHCT1 adjacent to each other in the first direction DR1. The second back source/drain contact 270 may connect the third source/drain pattern 250 and the second back wiring line 60.

The second back source/drain contact 270 may include a first side 270_S1 and a second side 270_S2 that are opposite to each other in the third direction DR3. The first side 270_S1 of the second back source/drain contact may face the third source/drain pattern 250. The first side 270_S1 of the second back source/drain contact may be connected to the third source/drain pattern 250. For example, the first side 270_S1 of the second back source/drain contact may be an interface between the second back source/drain contact 270 and the second back contact silicide film 255. The first side 270_S1 of the second back source/drain contact may be a connection side that connects the second back source/drain contact 270 and the third source/drain pattern 250. In the semiconductor device according to some embodiments, the first side 270_S1 of the second back source/drain contact may have a concave shape.

The second side 270_S2 of the second back source/drain contact may face the second back wiring line 60. The second side 270_S2 of the second back source/drain contact may be connected to the second back wiring line 60.

The second back contact silicide film 255 may be disposed between the second back source/drain contact 270 and the third source/drain pattern 250.

The description of the heights of the third source/drain pattern 250, the fourth source/drain pattern 260, the second sacrificial semiconductor pattern 260PH, and the second back source/drain contact 270 may be substantially the same as the description of the first source/drain pattern 150, the second source/drain pattern 160, the first sacrificial semiconductor pattern 160PH, and the first back source/drain contact 170.

Each of the first back source/drain contact 170 and the second back source/drain contact 270 includes a conductive material. Each of the first back source/drain contact 170 and the second back source/drain contact 270 may include at least one of, for example, a metal, a conductive metal nitride, a conductive metal carbide, a conductive metal oxide, a conductive metal oxynitride, a conductive metal silicon nitride, a conductive metal carbonitride or a two-dimensional material. Although each of the first back source/drain contact 170 and the second back source/drain contact 270 is shown to be a single film, this is only for convenience of explanation, and embodiments are not limited thereto. For example, each of the first back source/drain contact 170 and the second back source/drain contact 270 may have a multiple conductive film structure. Each of the first back source/drain contact 170 and the second back source/drain contact 270 may include a back contact barrier film and a back contact filling film.

Each of the first back contact silicide film 155 and the second back contact silicide film 255 may include a metal silicide material.

The first front source/drain contact 175 may extend long in the third direction DR3. The first front source/drain contact 175 may be connected to the second source/drain pattern 160. For example, the first front source/drain contact 175 is electrically connected to the second source/drain pattern 160.

The first front source/drain contact 175 may be disposed inside the first front interlayer insulating film 190 and the second source/drain pattern 160. A portion of the first front source/drain contact 175 may be disposed inside the second source/drain pattern 160.

The first front source/drain contact 175 may include a first side 175_S1 and a second side 175_S2 that are opposite to each other in the third direction DR3. The second side 175_S2 of the first front source/drain contact may face the second source/drain pattern 160. The second side 175_S2 of the first front source/drain contact may be connected to the second source/drain pattern 160. For example, the second side 175_S2 of the first front source/drain contact may be an interface between the first front source/drain contact 175 and a first front contact silicide film 165.

The second side 175_S2 of the first front source/drain contact may have a bowl shape. The second side 175_S2 of the first front source/drain contact may have a convex shape.

The second front source/drain contact 275 may extend long in the third direction DR3. The second front source/drain contact 275 may be electrically connected to the fourth source/drain pattern 260. The second front source/drain contact 275 may be disposed inside the first front interlayer insulating film 190 and the fourth source/drain pattern 260.

The second front source/drain contact 275 may include a first side 275_S1 and a second side 275_S2 that are opposite to each other in the third direction DR3. The second side 275_S2 of the second front source/drain contact may be connected to the fourth source/drain pattern 260. The second side 275_S2 of the second front source/drain contact may have a convex shape.

Although the first front source/drain contact 175 and the second front source/drain contact 275 are shown to have a single conductive film structure, embodiments are not limited thereto. The first front source/drain contact 175 and the second front source/drain contact 275 may include at least one of, for example, a metal, a conductive metal nitride, a conductive metal carbide, a conductive metal oxide, a conductive metal carbonitride or a two-dimensional material.

The first front contact silicide film 165 may be disposed between the first front source/drain contact 175 and the second source/drain pattern 160. The second front contact silicide film 265 may be disposed between the second front source/drain contact 275 and the fourth source/drain pattern 260. The first front contact silicide film 165 and the second front contact silicide film 265 may include a metal silicide material.

The second front interlayer insulating film 191 may be disposed on the first front interlayer insulating film 190, the gate structure GS, the first front source/drain contact 175, and the second front source/drain contact 275. The second front interlayer insulating film 191 may include, for example, at least one of silicon oxide, silicon nitride, silicon carbonitride, silicon oxynitride, and a low dielectric constant material (i.e., a low-κ material).

The front wiring structure 195 may be disposed inside the second front interlayer insulating film 191. The front wiring structure 195 may be disposed on the first side 50_S1 of the first back wiring line and the first side of the second back wiring line 60. The front wiring structure 195 may include a front via plug 196 and a front wiring line 197.

The front wiring structure 195 may be connected to the first front source/drain contact 175 and the second front source/drain contact 275. The front wiring structure 195 may be connected to the first side 175_S1 of the first front source/drain contact and the first side 275_S1 of the second front source/drain contact. For example, the front wiring structure 195 may not be connected to the first source/drain pattern 150 connected to the first back source/drain contact 170, and may not be connected to the third source/drain pattern 250 connected to the second back source/drain contact 270.

In some embodiments, the front wiring structure 195 may be connected to the first source/drain pattern 150 through another front source/drain contact. That is, the front wiring structure 195 may be connected to the first back source/drain contact 170 via the first source/drain pattern 150.

Each of the front via plug 196 and the front wiring line 197 may include at least one of, for example, a metal, a conductive metal nitride, a conductive metal carbide, a conductive metal oxide, a conductive metal carbonitride or a two-dimensional material.

Although each of the front via plug 196 and the front wiring line 197 is shown as being a single conductive film structure, this is only for convenience of explanation, and embodiments are not limited thereto. For example, as an example, at least one of the front via plug 196 or the front wiring line 197 may have a multiple conductive film structure. As another example, the front wiring structure 195 may have an integral structure without a boundary division between the front via plug 196 and the front wiring line 197.

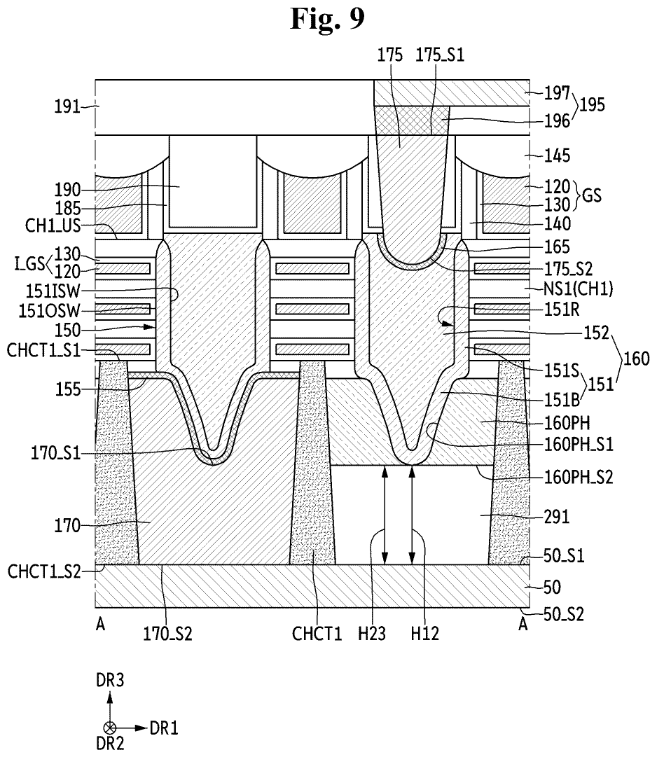

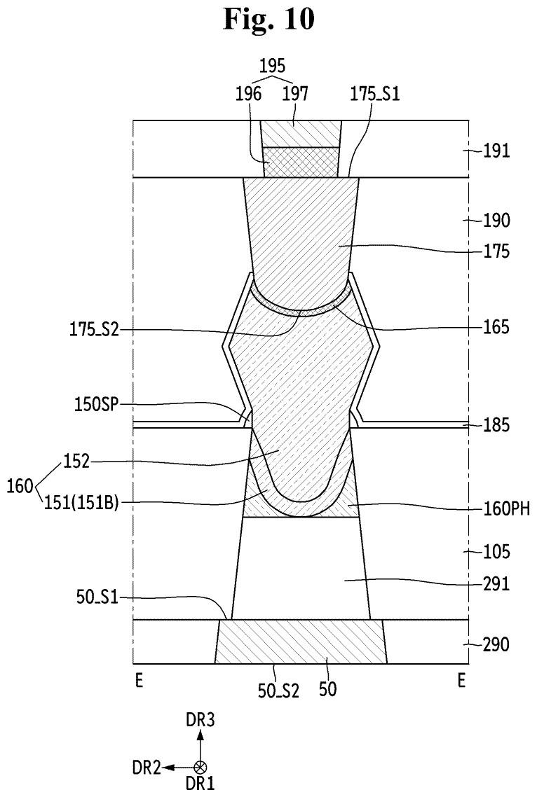

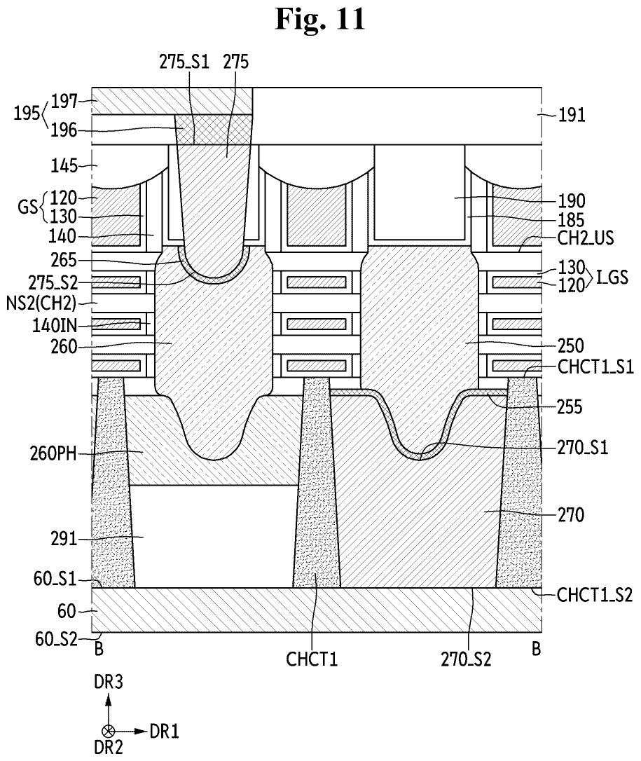

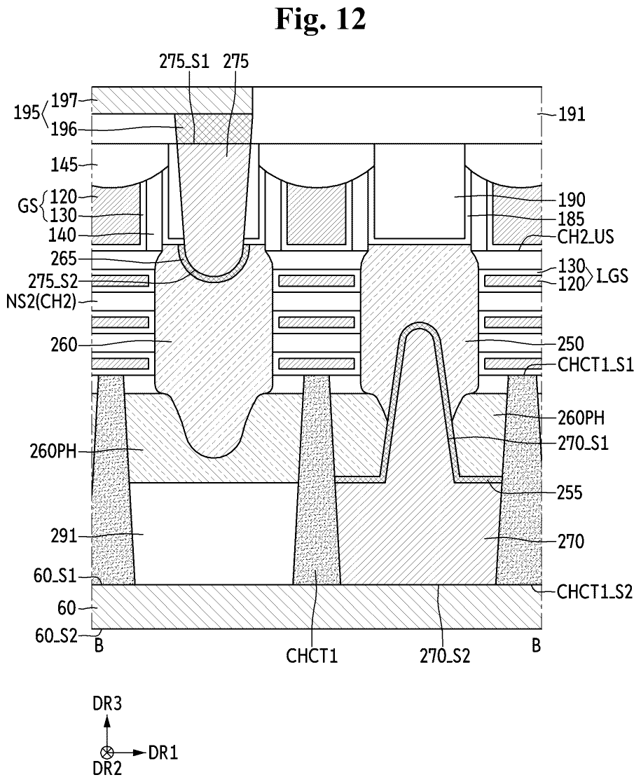

FIGS. 9 and 10 are diagrams for explaining a semiconductor device according to some embodiments. FIG. 11 is a diagram for explaining the semiconductor device according to some embodiments. FIG. 12 is a diagram for explaining the semiconductor device according to some embodiments. For convenience of explanation, different points from the contents explained using FIGS. 1 to 8 will be mainly explained.

Referring to FIGS. 9 and 10, in the semiconductor device according to some embodiments, a height H23 from the first side 50_S1 of the first back wiring line to the bottom side 160PH_S2 of the first sacrificial semiconductor pattern may be equal to the height H12 from the first side 50_S1 of the first back wiring line to the lowermost portion of the second source/drain pattern 160.

The second source/drain pattern 160 may extend up to the bottom side 160PH_S2 of the first sacrificial semiconductor pattern.

Referring to FIG. 11, the semiconductor device according to some embodiments may further include an inner spacer 140IN disposed between the second sheet patterns NS2 adjacent to each other in the third direction DR3.

The inner spacer 140IN may be disposed between the third source/drain pattern 250 and the inner gate structure I_GS, and between the fourth source/drain pattern 260 and the inner gate structure I_GS.

The inner spacer 140IN may include an insulating material.

As an example, the inner spacer 140IN may be disposed between the first sheet patterns NS1 adjacent to each other in the third direction DR3. As another example, the inner spacer 140IN may not be disposed between the first sheet patterns NS1 adjacent to each other in the third direction DR3.

Referring to FIG. 12, in the semiconductor device according to some embodiments, a portion of the second back source/drain contact 270 may be disposed inside the second sacrificial semiconductor pattern 260PH and the third source/drain pattern 250.

The second back source/drain contact 270 may penetrate the second sacrificial semiconductor pattern 260PH, and extend into the third source/drain pattern 250. The second back contact silicide film 255 may be disposed along the boundary between the second back source/drain contact 270 and the second sacrificial semiconductor pattern 260PH, and the boundary between the second back source/drain contact 270 and the third source/drain pattern 250.

The first side 270_S1 of the second back source/drain contact may have a convex shape.

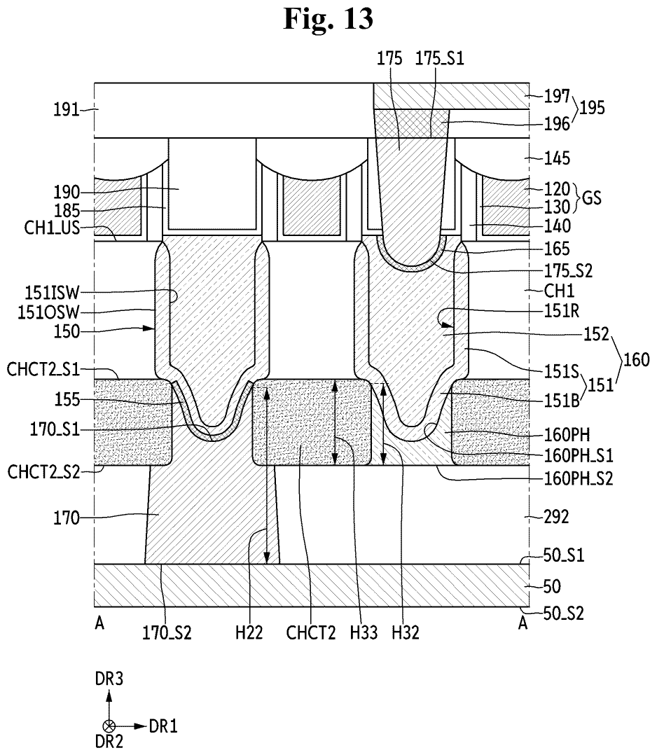

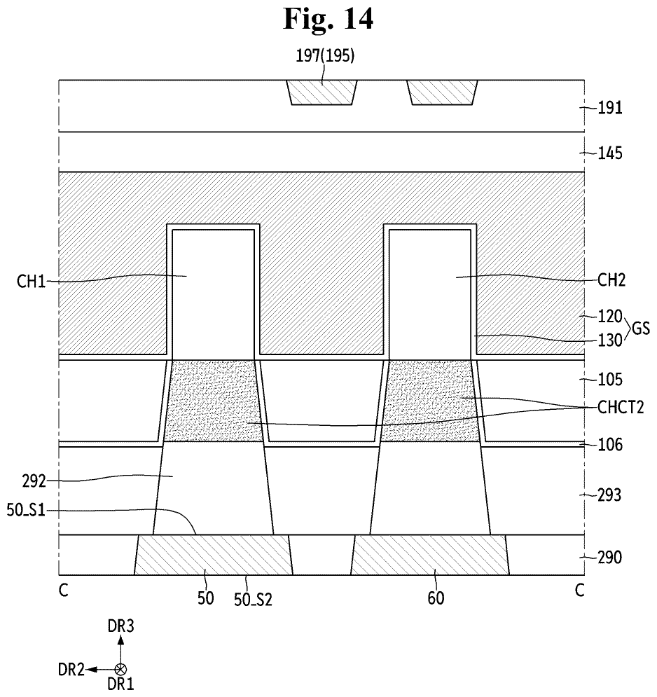

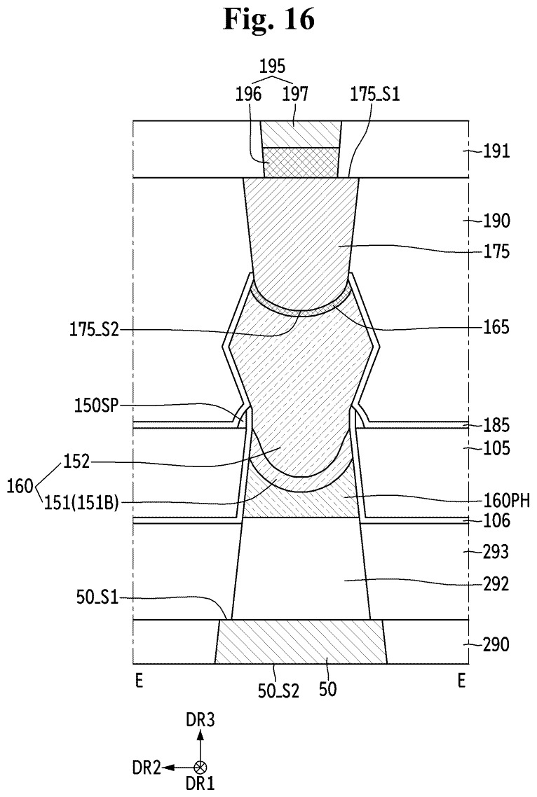

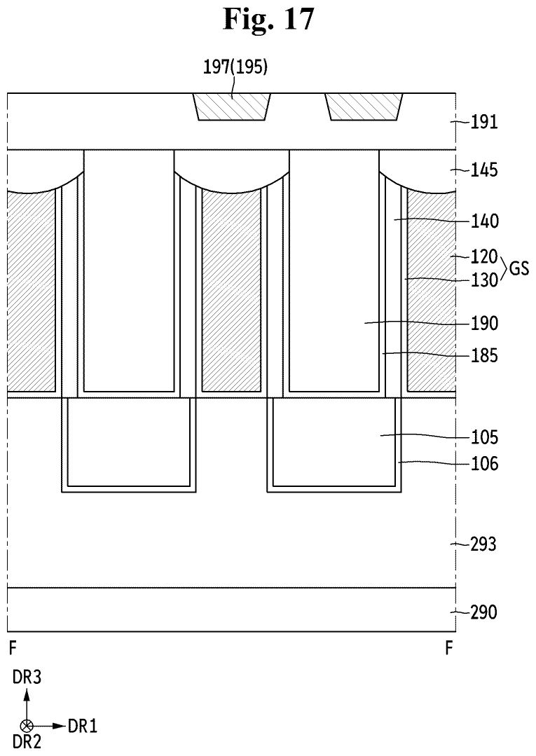

FIGS. 13 to 17 are diagrams for explaining a semiconductor device according to some embodiments. For convenience of explanation, different points from the contents explained using FIGS. 1 to 8 will be mainly explained.

For reference, the cross-sectional view taken along B-B of FIG. 1 may be similar to FIG. 13.

Referring to FIGS. 13 to 17, a semiconductor device according to some embodiments may include a second active region insulating pattern CHCT2 instead of the first active region insulating pattern CHCT1.

A second back insertion insulating film 292 may be disposed on the back interlayer insulating film 290. The second back insertion insulating film 292 may be disposed on the first side 50_S1 of the first back wiring line and the first side of the second back wiring line 60. The second back insertion insulating film 292 may extend in the first direction DR1.

The second back insertion insulating film 292 may be disposed between the first back wiring line 50 and the second source/drain pattern 160, and between the first back wiring line 50 and the first channel pattern CH1. The second back insertion insulating film 292 may be disposed between the second back wiring line 60 and the fourth source/drain pattern 260, and between the second back wiring line 60 and the second channel pattern CH2.

The second back insertion insulating film 292 may include at least one of, for example, silicon nitride, silicon oxynitride, silicon oxide, silicon oxycarbonitride, silicon boronitride, silicon oxyboronitride, silicon carbonitride, silicon oxycarbide or a low dielectric constant material (i.e., a low-κ material). As an example, the second back insertion insulating film 292 may include silicon oxide.

The second active region insulating pattern CHCT2 may be disposed between the first back wiring line 50 and the first channel pattern CH1. For example, the second active region insulating pattern CHCT2 may be disposed between the first channel pattern CH1 and the second back insertion insulating film 292.

The second active region insulating pattern CHCT2 may be disposed between the second back wiring line 60 and the second channel pattern CH2. For example, the second active region insulating pattern CHCT2 may be disposed between the second channel pattern CH2 and the second back insertion insulating film 292.

The second active region insulating pattern CHCT2 may be in contact with the first channel pattern CH1 and the second channel pattern CH2. The first sacrificial semiconductor pattern 160PH may be disposed between the second active region insulating patterns CHCT2 adjacent to each other in the first direction DR1. The first back source/drain contact 170 may be disposed between the second active region insulating patterns CHCT2 adjacent to each other in the first direction DR1. The second sacrificial semiconductor pattern 260PH and the second back source/drain contact 270 may be disposed between the second active region insulating patterns CHCT2 adjacent to each other in the first direction DR1.

The second active region insulating pattern CHCT2 may be in contact with the first source/drain pattern 150 and the second source/drain pattern 160. The second active region insulating pattern CHCT2 may be in contact with the third source/drain pattern 250 and the fourth source/drain pattern 260.

The second active region insulating pattern CHCT2 may include a first side CHCT2_S1 and a second side CHCT2_S2 that are opposite to each other in the third direction DR3. The first side CHCT2_S1 of the second active region insulating pattern may be in contact with the first channel pattern CH1. The first side CHCT2_S1 of the second active region insulating pattern may be in contact with the second channel pattern CH2. The second side CHCT2_S2 of the second active region insulating pattern may be in contact with the second back insertion insulating film 292.

For example, a portion of the first back source/drain contact 170 may be provided over the second side CHCT2_S2 of the second active region insulating pattern. The first back source/drain contact 170 may be in contact with a portion of the second side CHCT2_S2 of the second active region insulating pattern. In this regard, the first back source/drain contact 170 may extend along a portion of the second side CHCT2_S2 of the second active region insulating pattern.

A height H33 of the second active region insulating pattern CHCT2 in the third direction DR3 may be greater than or equal to a height H32 of the first sacrificial semiconductor pattern 160PH in the third direction DR3. The height H32 of the first sacrificial semiconductor pattern 160PH in the third direction DR3 may be a height from the bottom side 160PH_S2 of the first sacrificial semiconductor pattern to the uppermost portion of the contact side 160PH_S1 of the first sacrificial semiconductor pattern.

For example, the height H22 of the first back source/drain contact 170 in the third direction DR3 may be greater than the height H33 of the second active region insulating pattern CHCT2 in the third direction DR3.

The second active region insulating pattern (CHCT2) may include, for example, at least one of silicon nitride, silicon oxynitride, silicon oxide, silicon oxycarbonitride, silicon boronitride, silicon oxyboronitride, silicon carbonitride or silicon oxycarbide. As an example, the second active region insulating pattern CHCT2 may include silicon nitride.

A third back insertion insulating film 293 may be disposed on the back interlayer insulating film 290. The third back insertion insulating film 293 may be on (and for example may cover) a side wall of the second back insertion insulating film 292. The third back insertion insulating film 293 may be on (and for example may cover) a portion of a side wall of the first back source/drain contact 170.

For example, the third back insertion insulating film 293 may be formed simultaneously with the second active region insulating pattern CHCT2. The third back insertion insulating film 293 may include the same insulating material as that of the second active region insulating pattern CHCT2.

The field insulating film 105 may be disposed on the third back insertion insulating film 293.

The field insulating liner 106 may be disposed between the field insulating film 105 and the third back insertion insulating film 293. The field insulating liner 106 may extend along the boundary between the field insulating film 105 and the third back insertion insulating film 293, and the boundary between the field insulating film 105 and the second active region insulating pattern CHCT2.

The field insulating liner 106 may be on (and for example may cover) the remainder of the side wall of the first back source/drain contact 170. A portion of the field insulating liner 106 may be disposed on the side wall of the first source/drain pattern 150 and the side wall of the second source/drain pattern 160.

The field insulating liner 106 may be disposed between the first source/drain pattern 150 and the pin spacer 150SP, and between the second source/drain pattern 160 and the pin spacer 150SP.

A portion of the gate spacer 140 may include the same material as the field insulating liner 106. The field insulating liner 106 may include at least one of, for example, silicon nitride, silicon oxynitride, silicon oxycarbonitride, silicon boronitride, silicon oxyboronitride, silicon carbonitride or silicon oxycarbide. As an example, the field insulating liner 106 may include silicon nitride.

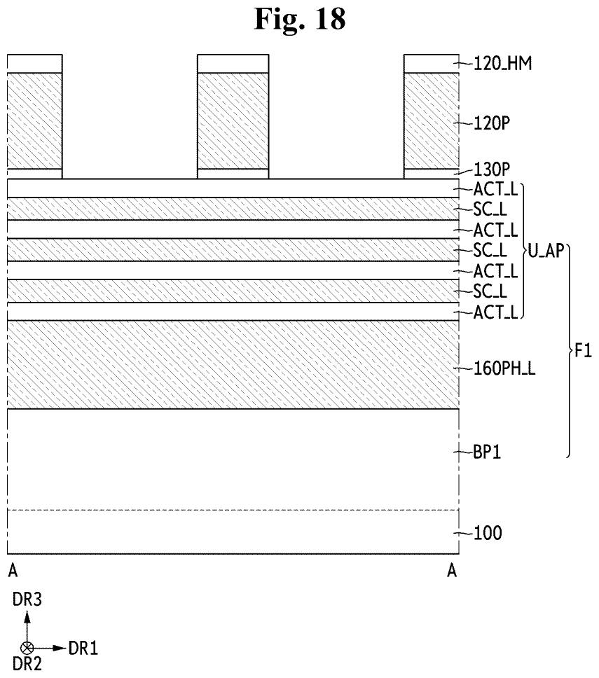

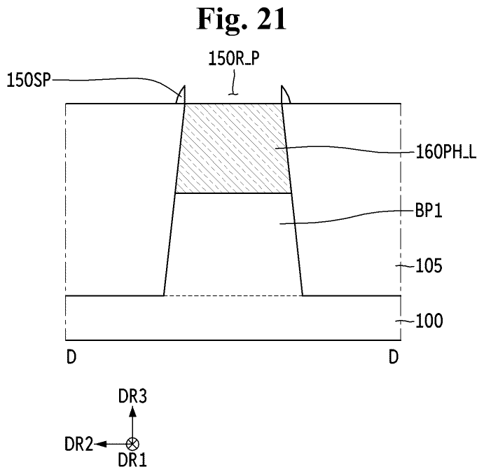

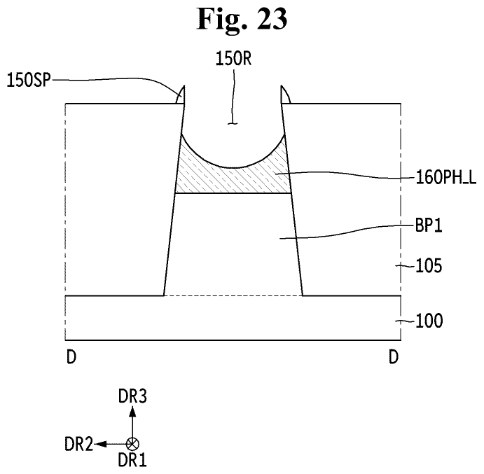

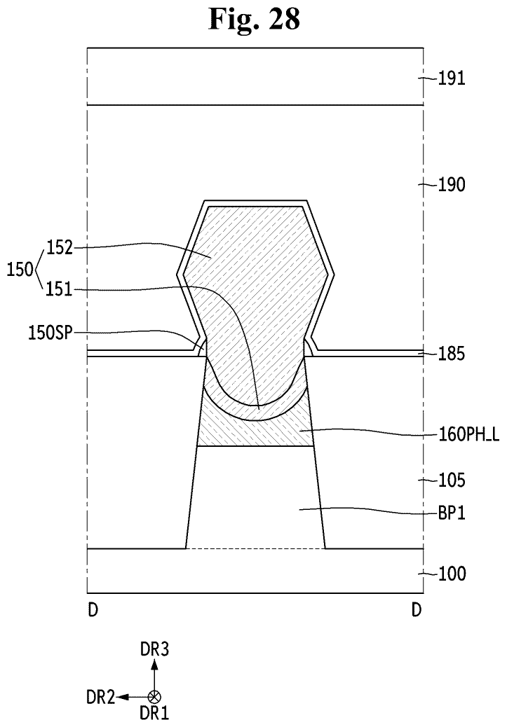

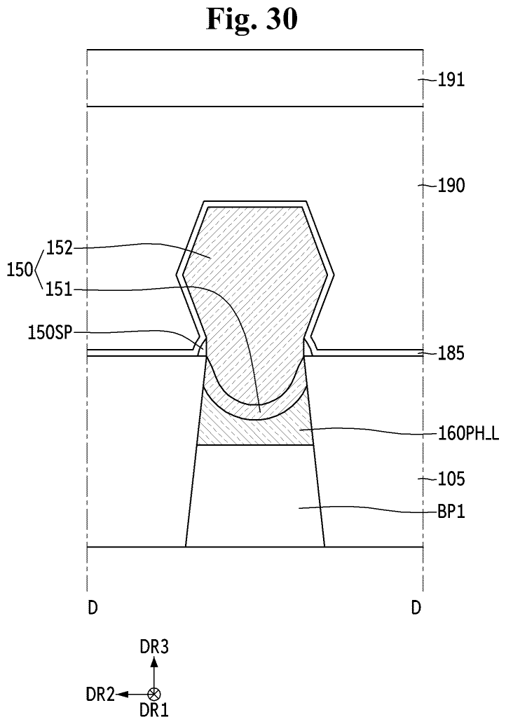

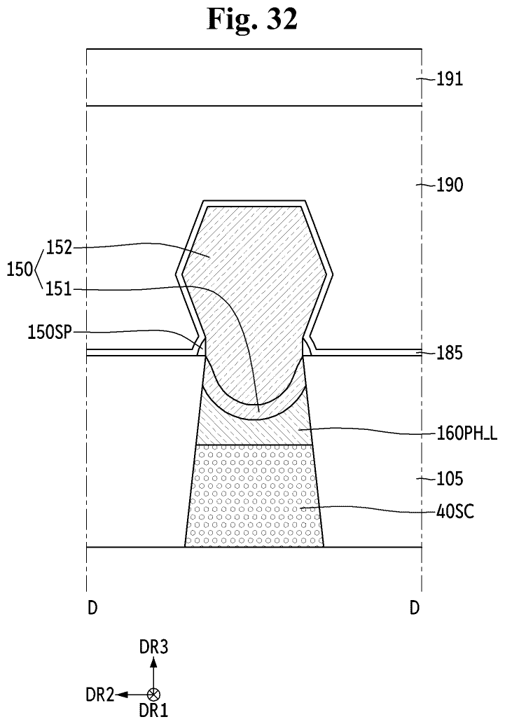

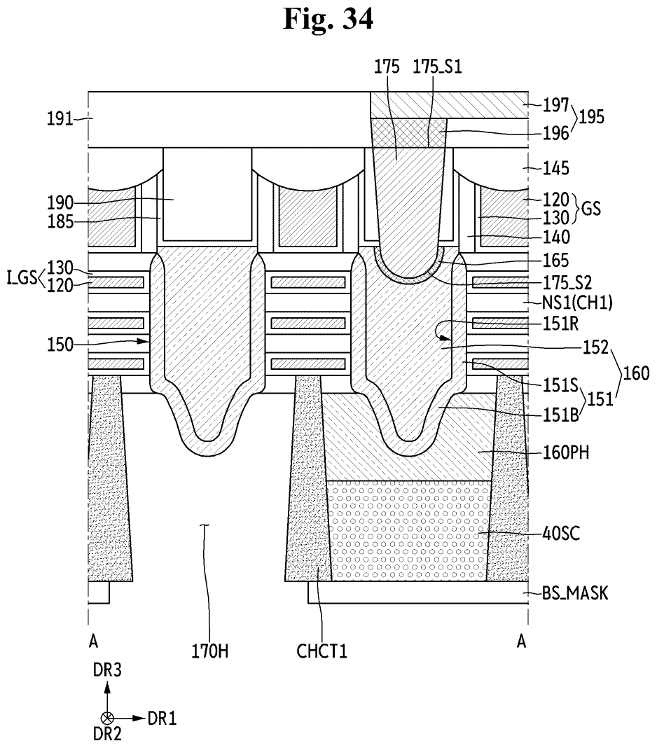

FIGS. 18 to 35 are intermediate stage diagrams for explaining a method for fabricating a semiconductor device according to some embodiments. For reference, FIGS. 18 to 35 may correspond to a method for fabricating the semiconductor device described using FIGS. 1 to 8.

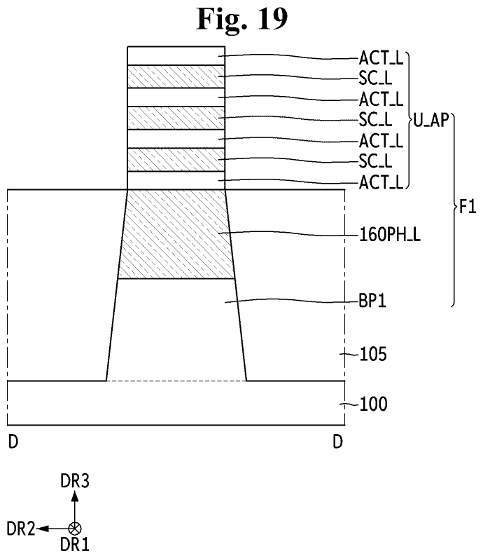

Referring to FIGS. 18 and 19, a fin-shaped pattern F1 may be formed on the substrate 100.

The substrate 100 may be bulk silicon or silicon-on-insulator (SOI). In contrast, the substrate 100 may be a silicon substrate, or may include other materials, for example, silicon germanium, silicon germanium-on-insulator (SGOI), indium antimonide, lead telluride, indium arsenide, indium phosphide, gallium arsenide or gallium antimonide.

The fin-shaped pattern F1 may include a lower pattern BP1, a sacrificial semiconductor film 160PH_L, and an upper pattern U_AP. The upper pattern U_AP may include a plurality of sacrificial channel patterns SC_L and a plurality of active patterns ACT_L that are stacked alternately on the sacrificial semiconductor film 160PH_L.

For example, each of the sacrificial semiconductor film 160PH_L and the sacrificial channel pattern SC_L may include a silicon-germanium film. The active pattern ACT_L may include a silicon film. The fraction of germanium of the sacrificial semiconductor film 160PH_L may be equal to or different from the fraction of germanium of the sacrificial channel pattern SC_L.

Next, the field insulating film 105 may be formed on the substrate 100. The field insulating film 105 may be on (and for example may cover) a portion of the side wall of the fin-shaped pattern F1.

Next, a dummy gate insulating film 130P, a dummy gate electrode 120P, and a dummy gate capping film 120_HM may be formed on the upper pattern U_AP and the field insulating film 105. The dummy gate electrode 120P may intersect the fin-shaped pattern F1.

The dummy gate insulating film 130P may include, for example, but is not limited to, silicon oxide. The dummy gate electrode 120P may include, for example, but is not limited to, polysilicon. The dummy gate capping film 120_HM may include, for example, but is not limited to, silicon nitride.

Referring to FIGS. 18 to 21, a pre-gate spacer 140P may be formed on the side wall of the dummy gate electrode 120P.

While the pre-gate spacer 140P is formed, a pre-source/drain recess 150R_P may be formed in the upper pattern U_AP, by using the dummy gate electrode 120P as a mask. The bottom side of the pre-source/drain recess 150R_P may be defined by the sacrificial semiconductor film 160PH_L.

While the pre-gate spacer 140P is formed, a fin spacer 150SP may be formed on the field insulating film 105.

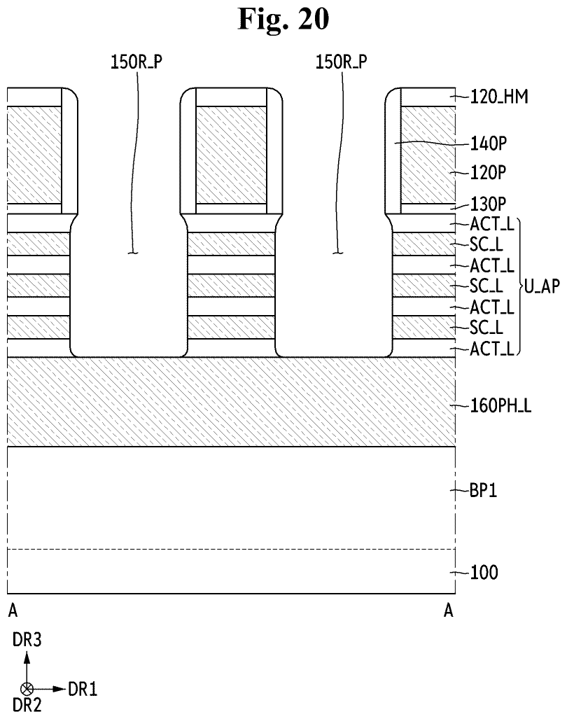

Referring to FIGS. 20 to 23, a source/drain recess 150R may be formed inside the fin-shaped pattern F1 through an additional etching process.

The source/drain recess 150R may be formed inside the upper pattern U_AP and the sacrificial semiconductor film 160PH_L. After forming the pre-source/drain recess 150R_P, the depth of the pre-source/drain recess 150R_P may be increased, using an anisotropic etching process. Accordingly, the source/drain recess 150R may be formed. The source/drain recess 150R may not be formed inside the lower pattern BP1.

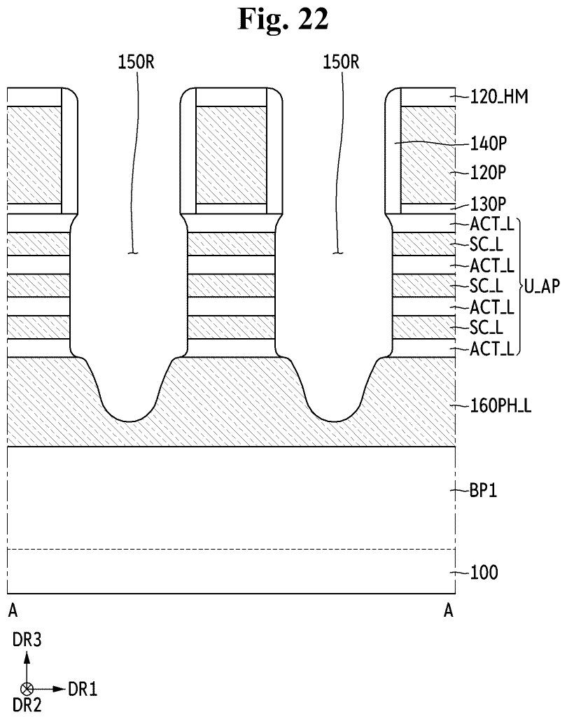

Referring to FIGS. 22 to 25, the first source/drain pattern 150 and the second source/drain pattern 160 may be formed inside the source/drain recess 150R.

More specifically, the semiconductor liner film 151 may be formed along the side wall and bottom side of the first source/drain recess 150R. The semiconductor liner film 151 may be formed, using an epitaxial growth method. The semiconductor liner film 151 may be doped with p-type impurities. Next, the bottom portion of the semiconductor liner film 151 may be additionally doped with p-type impurities, using a directional doping process. The semiconductor filling film 152 may be formed on the semiconductor liner layer 151. The semiconductor filling film 152 may be formed inside the liner recess 151R. Accordingly, the first source/drain pattern 150 and the second source/drain pattern 160 may be formed.

The source/drain etching stop film 185 and the first front interlayer insulating film 190 may be formed sequentially on the first source/drain pattern 150 and the second source/drain pattern 160.

Next, a portion of the first front interlayer insulating film 190, a portion of the source/drain etching stop film 185, and the dummy gate capping layer 120_HM may be removed to expose the upper side of the dummy gate electrode 120P. While the upper side of the dummy gate electrode 120P is exposed, a gate spacer 140 may be formed.

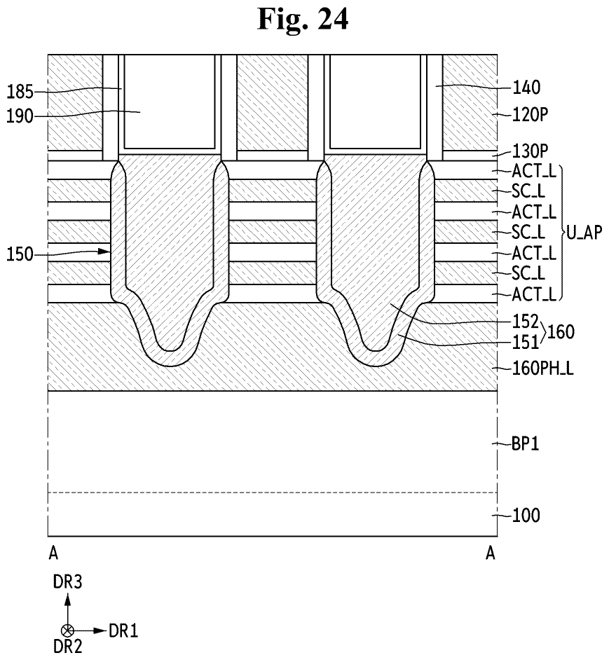

Referring to FIGS. 24 to 26, the dummy gate insulating film 130P and the dummy gate electrode 120P may be removed to expose the upper pattern U_AP between the gate spacers 140.

Next, the sacrificial channel pattern SC_L may be removed to form a first channel pattern CH1 including a plurality of first sheet patterns NS1. The first channel pattern CH1 may be connected to the first source/drain pattern 150 and the second source/drain pattern 160.

The sacrificial channel pattern SC_L may be removed to form a gate trench 120t between the gate spacers 140. When the sacrificial channel pattern SC_L is removed, a portion of the first source/drain pattern 150 and the second source/drain pattern 160 may be exposed.

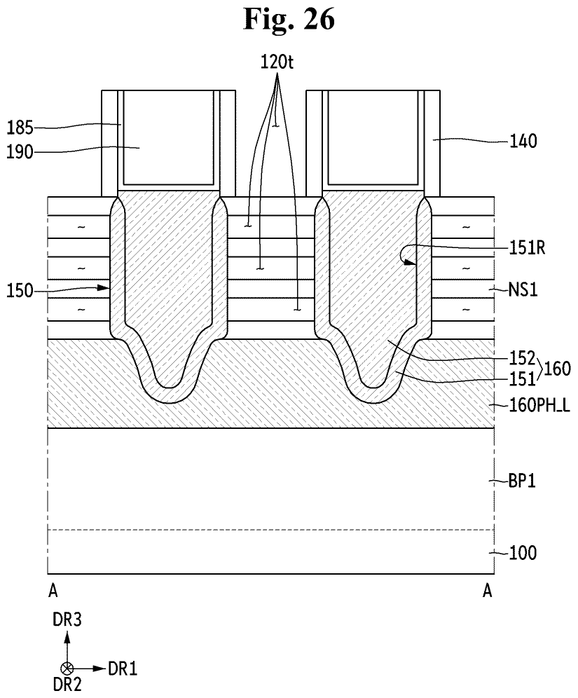

Referring to FIGS. 26 to 28, the gate insulating film 130 and the gate electrode 120 may be formed inside the gate trench 120t.

The gate capping pattern 145 may be formed on the gate electrode 120.

Next, the first front source/drain contact 175 may be formed on the upper side of the substrate 100. The first front source/drain contact 175 may be connected to the second source/drain pattern 160. Before the first front source/drain contact 175 is formed, the first front contact silicide film 165 may be formed on the second source/drain pattern 160.

Next, the front wiring structure 195 may be formed on the gate structure GS and the first front source/drain contact 175. The front wiring structure 195 may be connected to the first front source/drain contact 175.

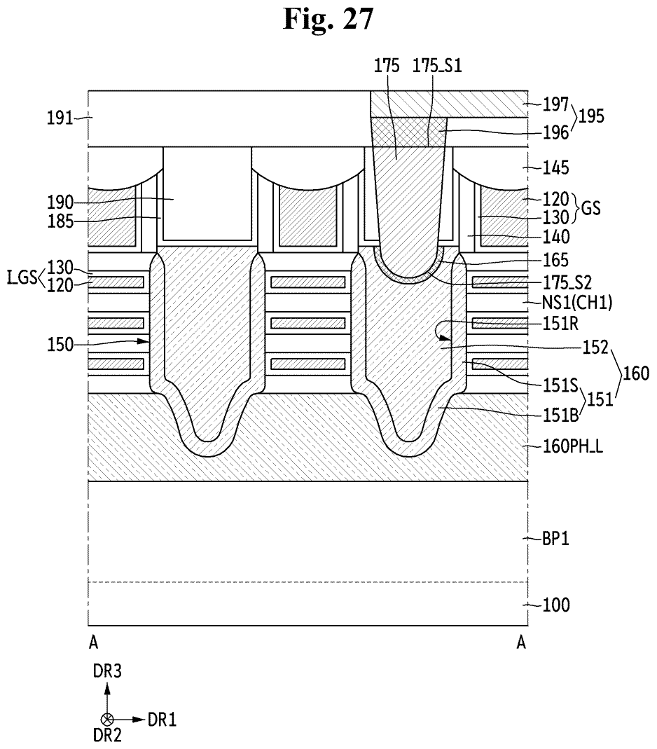

Referring to FIGS. 27 to 30, after forming the front wiring structure 195, the substrate 100 may be removed.

The substrate 100 is removed, and the lower pattern BP1 and the field insulating film 105 may be exposed.

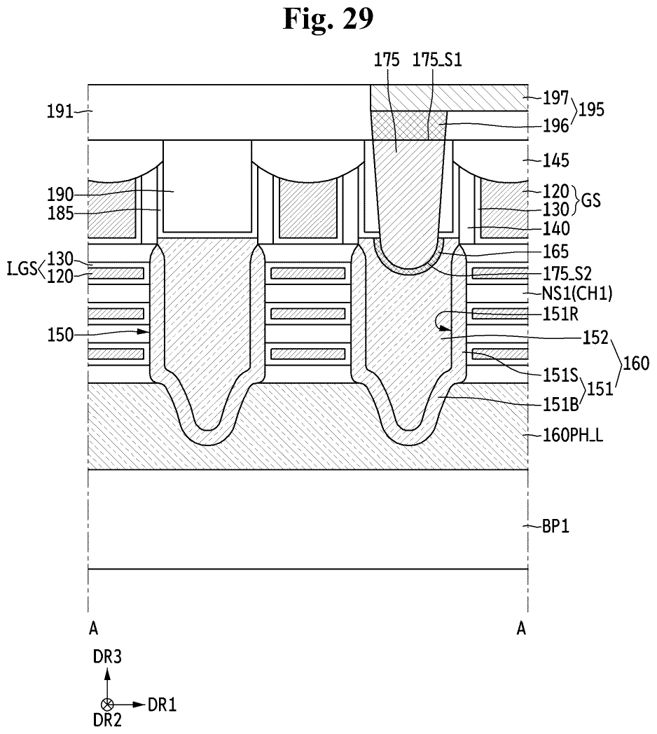

Referring to FIGS. 29 to 32, the exposed lower pattern BP1 may be removed.

After the lower pattern BP1 is removed, a sacrificial filling film 40SC may be formed in the space from which the lower pattern BP1 is removed. The field insulating layer 105 may be disposed on a side wall of the sacrificial filling film 40SC.

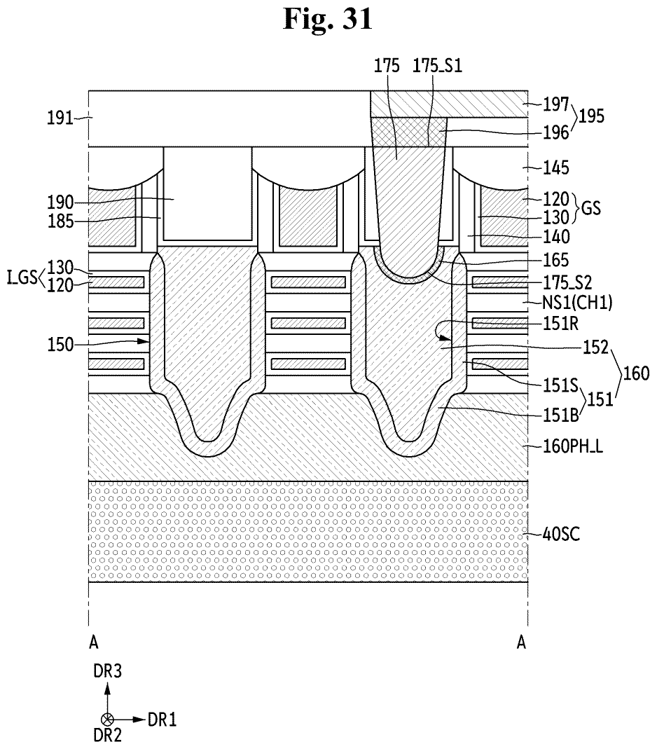

Referring to FIGS. 31 to 33, a plurality of first active region insulating patterns CHCT1 may be formed.

The first active region insulating pattern CHCT1 may penetrate the sacrificial filling film 40SC and the sacrificial semiconductor film 160PH_L. The first active region insulating pattern CHCT1 may extend up to the inner gate structure I_GS.

While the first active region insulating pattern CHCT1 is formed, the first active region insulating pattern CHCT1 may separate the sacrificial semiconductor film 160PH_L. Thus, the first sacrificial semiconductor pattern 160PH may be formed. The first sacrificial semiconductor pattern 160PH may be formed between the first active region insulating patterns CHCT1 adjacent to each other in the first direction DR1.

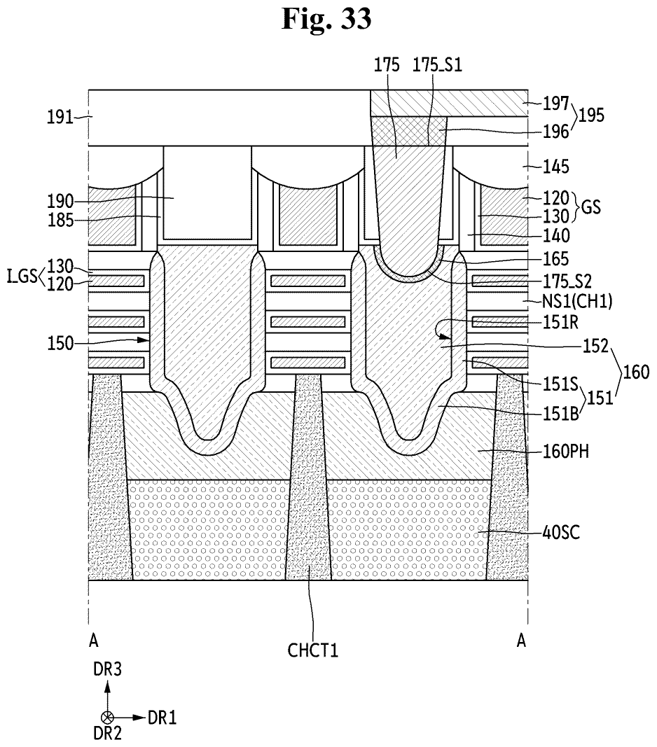

Referring to FIGS. 33 to 35, a back mask pattern BS_MASK may be formed on the first active region insulating pattern CHCT1 and the sacrificial filling film 40SC.

The sacrificial filling film 40SC and the first sacrificial semiconductor pattern 160PH disposed under the first source/drain pattern 150 may be removed, using the back mask pattern BS_MASK as a mask. The sacrificial filling film 40SC and the first sacrificial semiconductor pattern 160PH between the first active region insulating patterns CHCT1 adjacent to each other in the first direction DR1 are removed, and a back contact hole 170H that exposes the first source/drain pattern 150 may be formed. The side wall of the back contact hole 170H may be defined by the first active region insulating pattern CHCT1 and the field insulating film 105.

Because the back contact hole 170H is formed by removing the first sacrificial semiconductor pattern 160PH, the back contact hole 170H may not extend into the first source/drain pattern 150.

In this regard, the first source/drain pattern 150 may not be removed while the back contact hole 170H is formed. Alternatively, even if a portion of the semiconductor liner film 151 is removed while removing the first sacrificial semiconductor pattern 160PH, the semiconductor filling film 152 may not be exposed.

In addition, after the first source/drain pattern 150 is exposed by the back contact hole 170H, the semiconductor liner film 151 may be doped with additional p-type impurities.

Next, referring to FIGS. 2 and 5, the first back source/drain contact 170 may be formed inside the back contact hole 170H. The first back source/drain contact 170 may fill the back contact hole 170H. The first back source/drain contact 170 may be connected to the first source/drain pattern 150.

As an example, the back mask pattern BS_MASK may be removed after the back contact hole 170H is formed. As another example, the back mask pattern BS_MASK may be removed after the first back source/drain contact 170 is formed.

Next, after removing the sacrificial filling film 40SC, the first back insertion insulating film 291 may be formed in the space from which the sacrificial filling film 40SC is removed. Next, the first back wiring line 50 connected to the first back source/drain contact 170 may be formed.

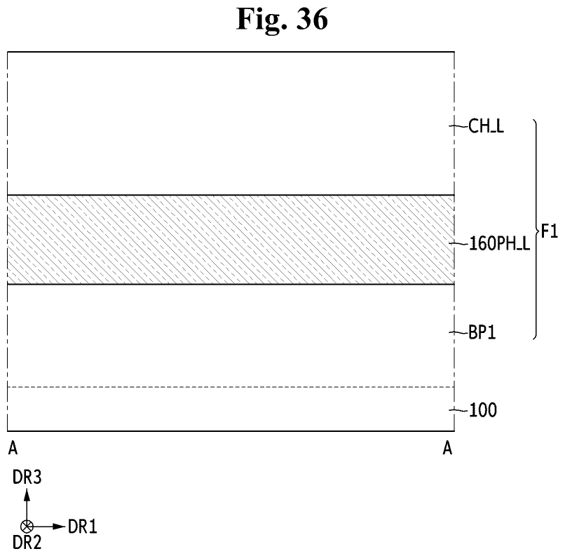

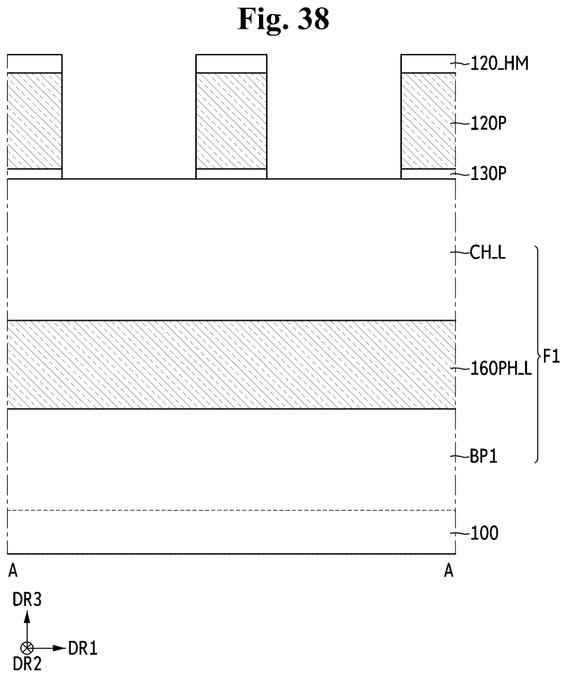

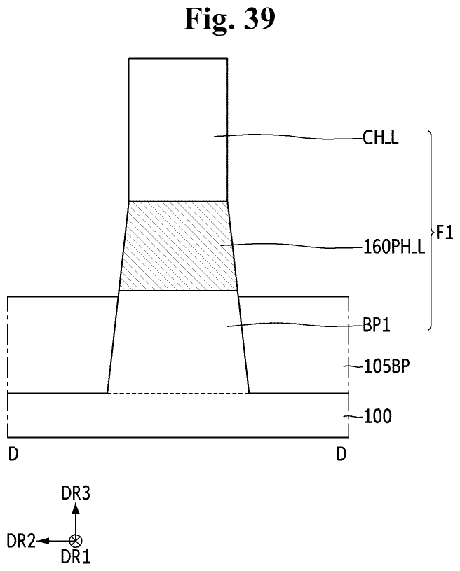

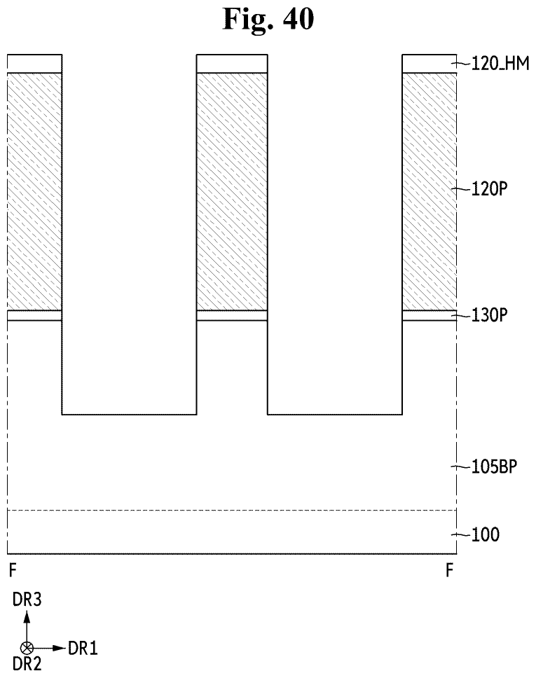

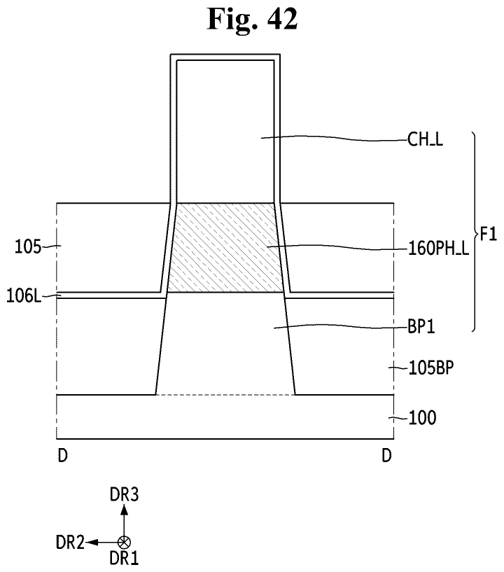

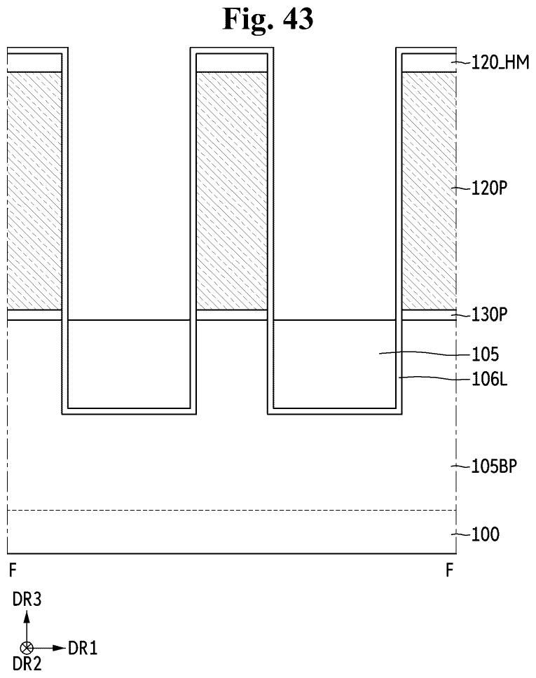

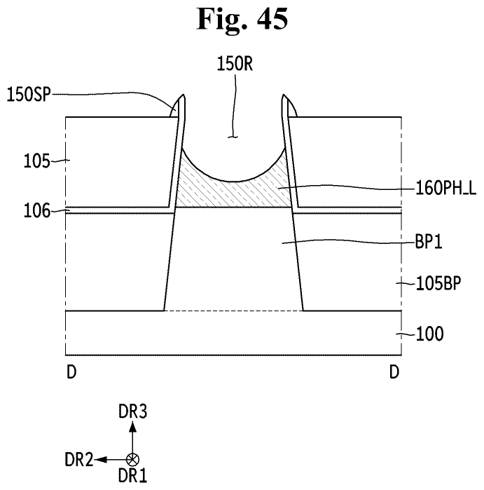

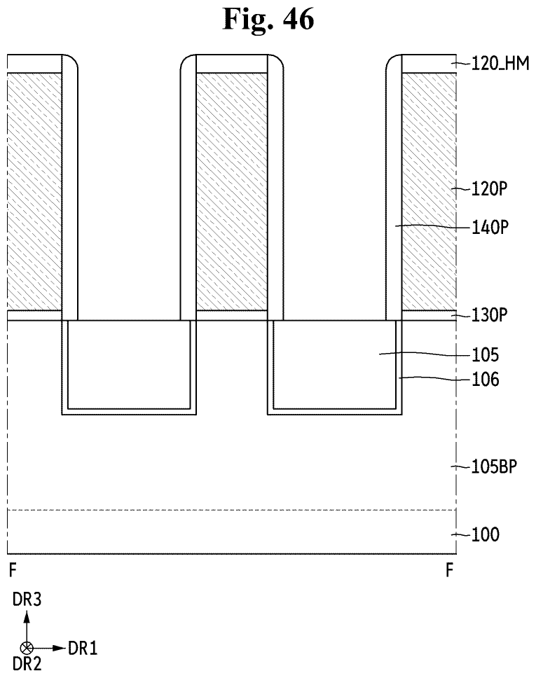

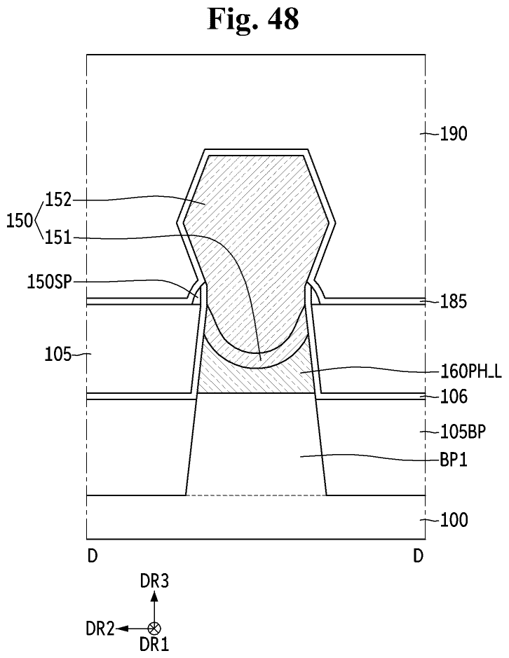

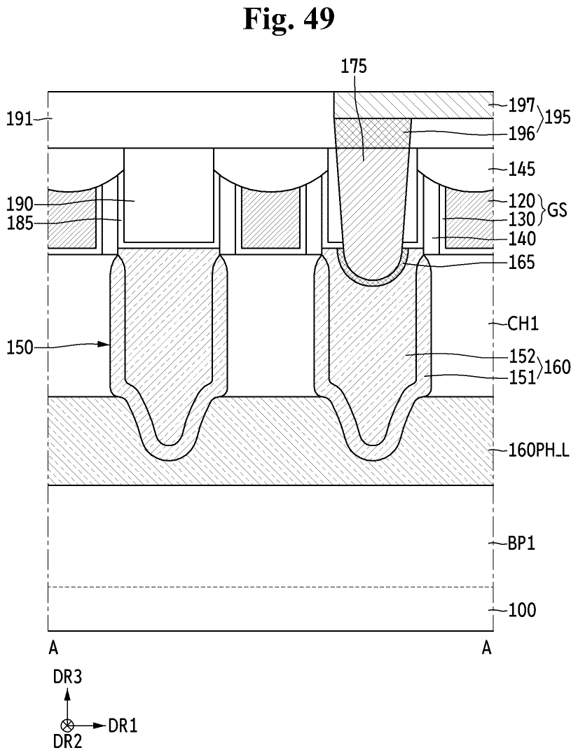

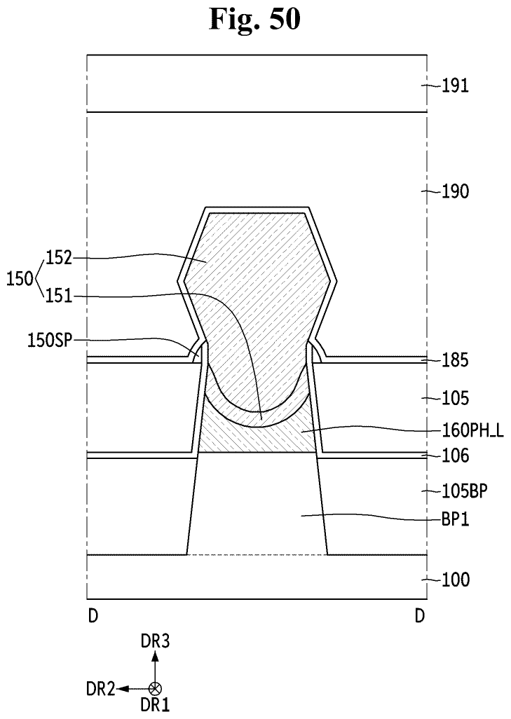

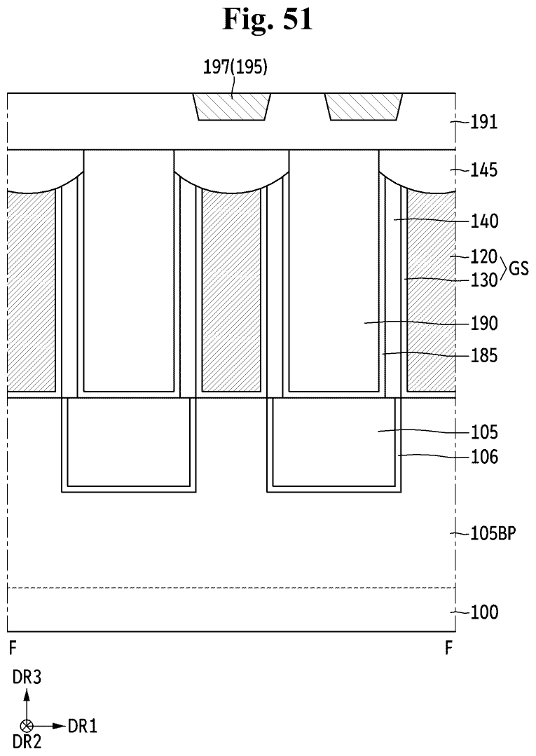

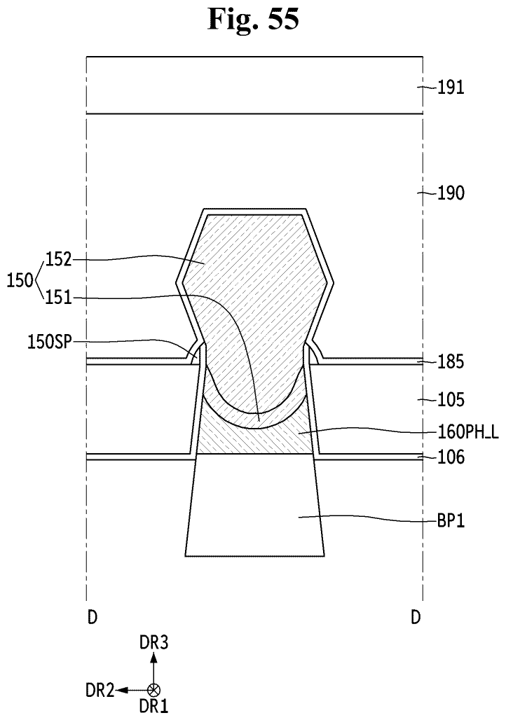

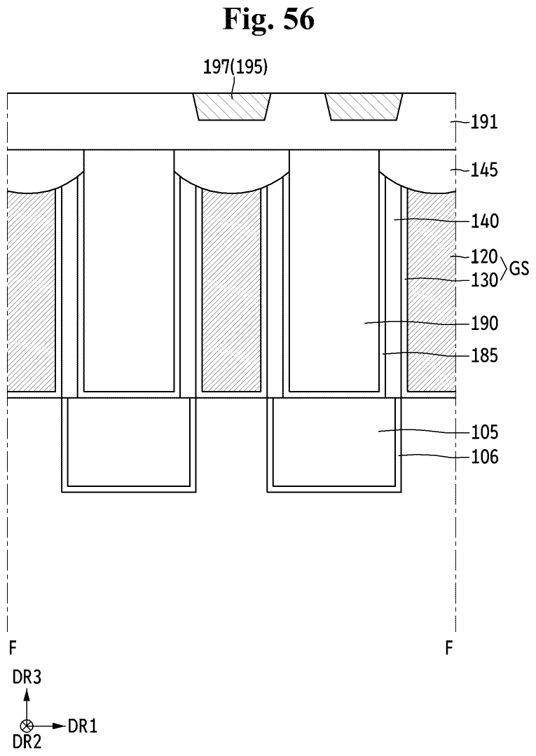

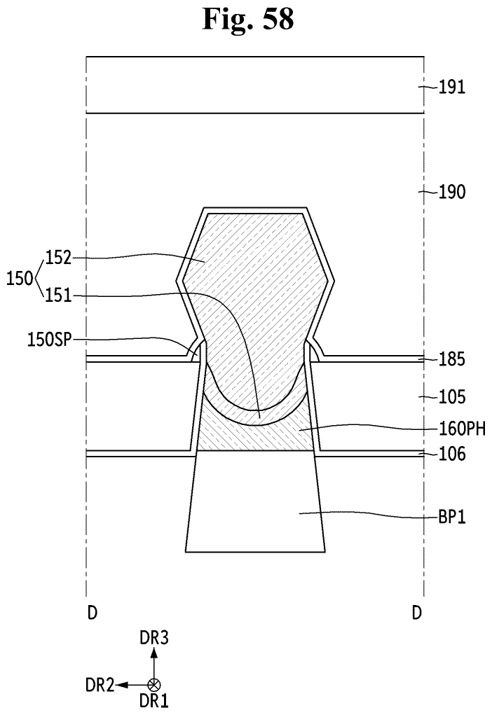

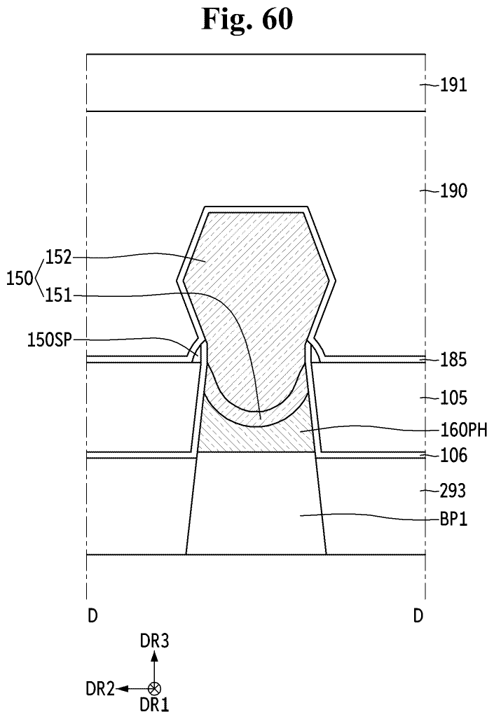

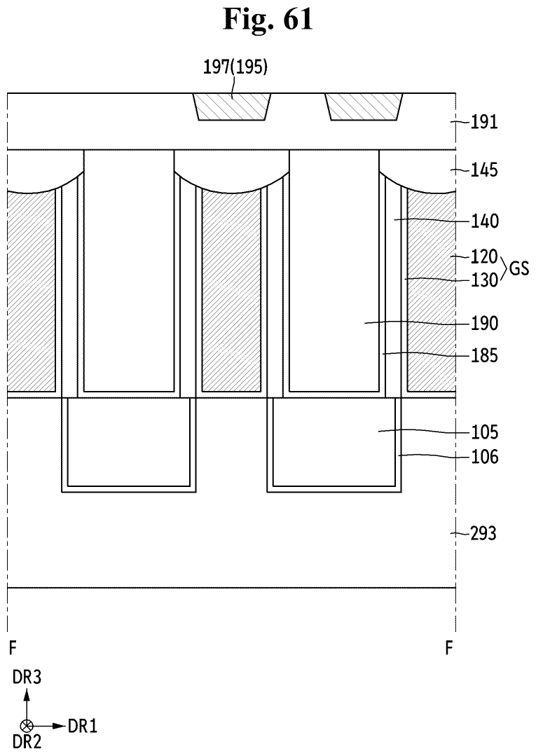

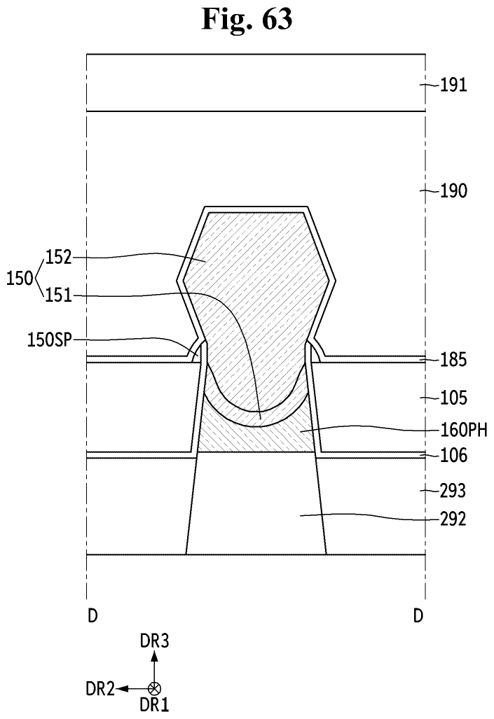

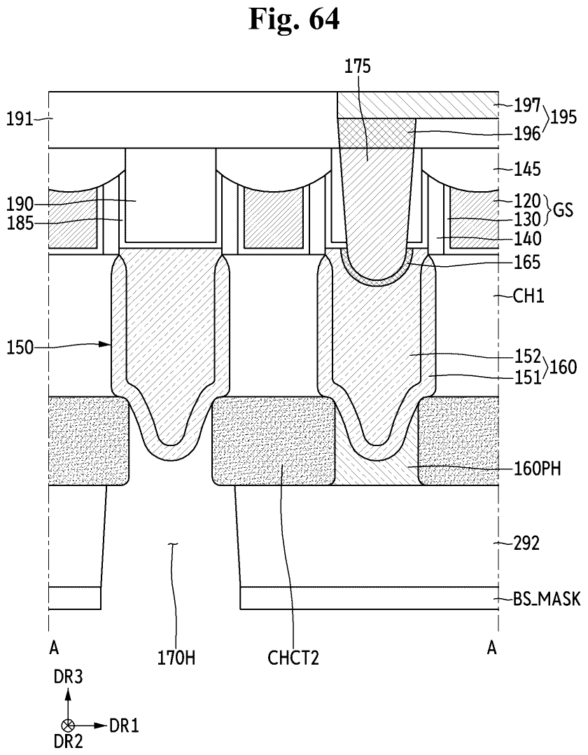

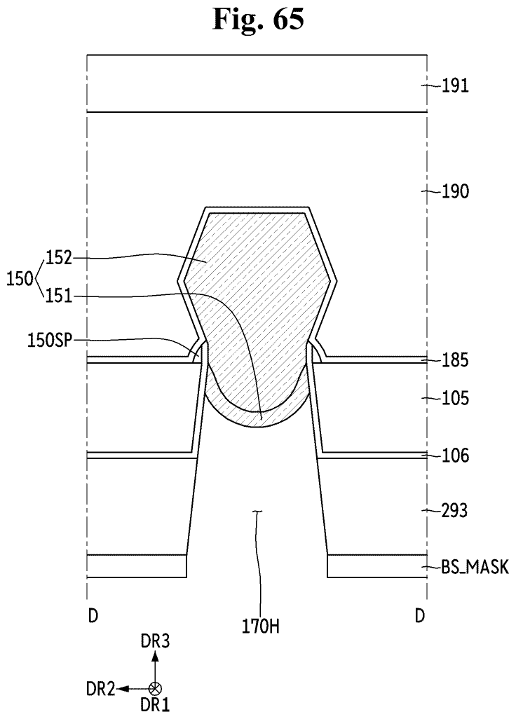

FIGS. 36 to 65 are intermediate stage diagrams for explaining a method for fabricating a semiconductor device according to some embodiments. For reference, FIGS. 36 to 65 may correspond to a method for fabricating the semiconductor device described using FIGS. 13 to 17.

Repeated contents of the fabricating method described using FIGS. 18 to 35 will be omitted.

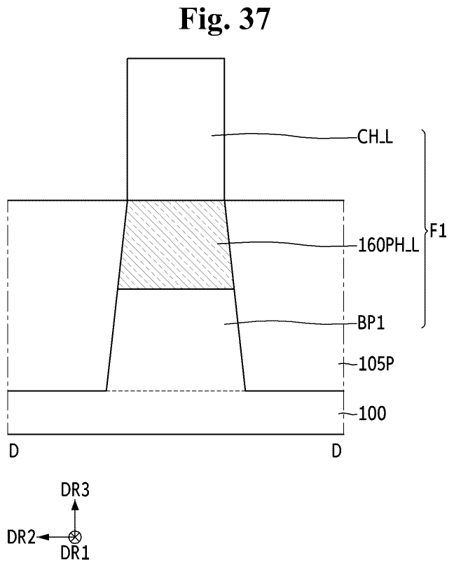

Referring to FIGS. 36 and 37, a fin-shaped pattern F1 including the lower pattern BP1, the sacrificial semiconductor film 160PH_L, and the channel film CH_L may be formed on the substrate 100.

The channel film CH_L may include, but is not limited to, a silicon film. That is, the channel film CH_L may include a silicon-germanium film having an etching selectivity with respect to the sacrificial semiconductor film 160PH_L.

Subsequently, a pre-field insulating film 105P may be formed on the substrate 100. The pre-field insulating film 105P may be on (and for example may cover) a portion of the side wall of the fin-shaped pattern F1. For example, the pre-field insulating film 105P may be on (and for example may cover) the side wall of the lower pattern BP1 and the side wall of the sacrificial semiconductor film 160PH_L.

Referring to FIGS. 36 to 40, the dummy gate insulating film 130P, the dummy gate electrode 120P, and the dummy gate capping film 120_HM may be formed on the channel film CH_L and the pre-field insulating film 105P.

The dummy gate electrode 120P may intersect the fin-shaped pattern F1.

Next, a portion of the pre-field insulating film 105P may be removed, using the dummy gate electrode 120P as a mask. Accordingly, the lower field insulating film 105BP may be formed on the substrate 100. The dummy gate electrode 120P may be disposed on the lower field insulating film 105BP.

A portion of the pre-field insulating film 105P that does not overlap the dummy gate electrode 120P in the third direction DR3 is removed, and the lower field insulating film 105BP may be formed. As a result, a sacrificial semiconductor film 160PH_L that does not overlap the dummy gate electrode 120P in the third direction DR3 may be exposed. For example, a side wall of the sacrificial semiconductor film 160PH_L may be exposed. In this regard, the lower field insulating film 105BP may expose the side wall of the sacrificial semiconductor film 160PH_L.

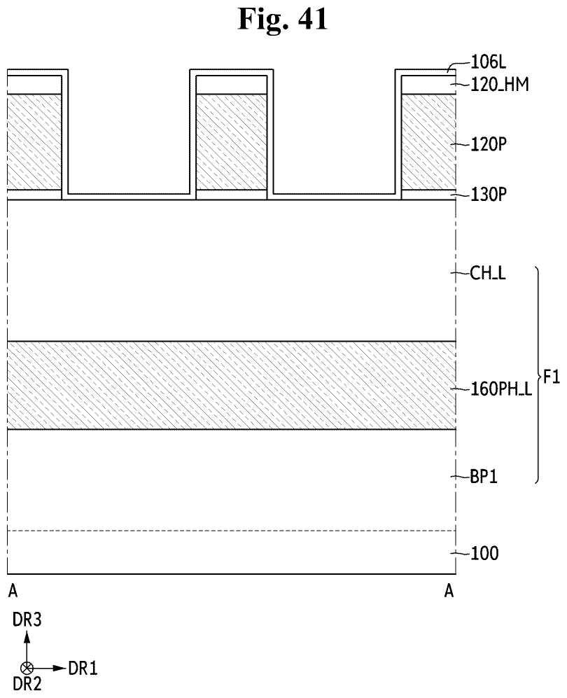

Referring to FIGS. 41 to 43, a field insulating liner film 106L may be formed on the fin-shaped pattern F1 and the lower field insulating film 105BP.

The field insulating liner film 106L may extend along the side wall of the dummy gate electrode 120P, the side wall of the sacrificial semiconductor film 160PH_L, the side wall of the channel film CH_L, and the upper side of the lower field insulating film 105BP. The field insulating liner film 106L may be formed along the side wall of the exposed sacrificial semiconductor film 160PH_L and the side wall of the exposed channel film CH_L.

The field insulating liner film 106L may be formed, for example, but is not limited to, by using an atomic layer deposition (ATOM) method.

Next, the field insulating film 105 may be formed on the field insulating liner film 106L. The field insulating film 105 may be on (and for example may cover) the side wall of the sacrificial semiconductor film 160PH_L.

Referring to FIGS. 41 to 46, a spacer film may be formed on the field insulating liner film 106L and the field insulating film 105.

The spacer film may extend along the upper side of the field insulating film 105, the side wall of the dummy gate electrode 120P, and the side wall of the channel film CH_L.

Next, the source/drain recess 150R may be formed inside the fin-shaped pattern F1, using the dummy gate electrode 120P as a mask. The source/drain recess 150R may be formed as described using FIGS. 20 to 23.

The source/drain recess 150R may separate the channel film CH_L. Accordingly, the first channel pattern CH1 may be formed on the sacrificial semiconductor film 160PH_L.

While the source/drain recess 150R is formed, the spacer film and the field insulating liner film 106L may be etched to form the pre-gate spacer 140P on the side wall of the dummy gate electrode 120P. For example, the spacer film and the field insulating liner film 106L may be etched, using an anisotropic etching process. The field insulating liner film 106L on the side wall of the dummy gate electrode 120P may be a portion of the pre-gate spacer 140P. The field insulating liner film 106L may be etched to form a field insulating liner 106 between the lower field insulating film 105BP and the field insulating film 105. A portion of the spacer film remains, and a fin spacer 150SP may be formed on the field insulating film 105.

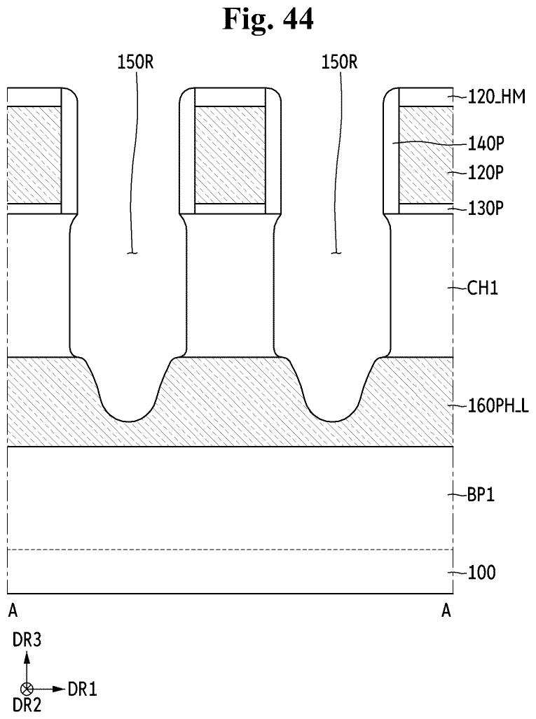

Referring to FIGS. 44 to 48, the first source/drain pattern 150 and the second source/drain pattern 160 may be formed inside the source/drain recess 150R.

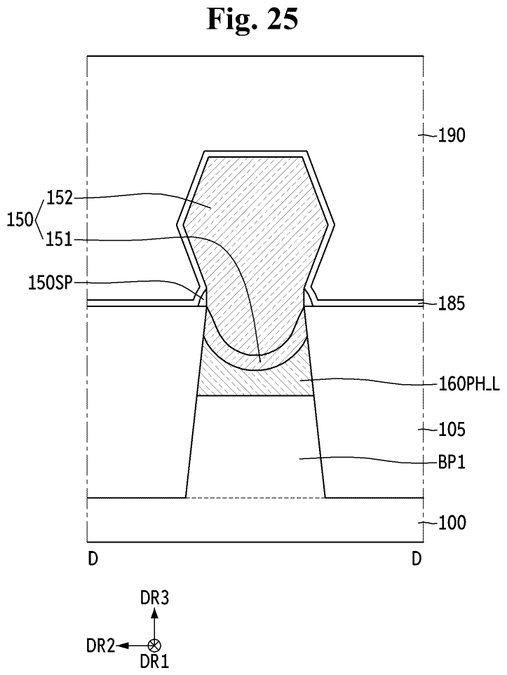

The first source/drain pattern 150 and the second source/drain pattern 160 may be formed as described using FIGS. 24 and 25.

Next, a source/drain etching stop film 185 and a first front interlayer insulating film 190 may be formed sequentially on the first source/drain pattern 150 and the second source/drain pattern 160. While the upper side of the dummy gate electrode 120P is exposed, a gate spacer 140 may be formed.

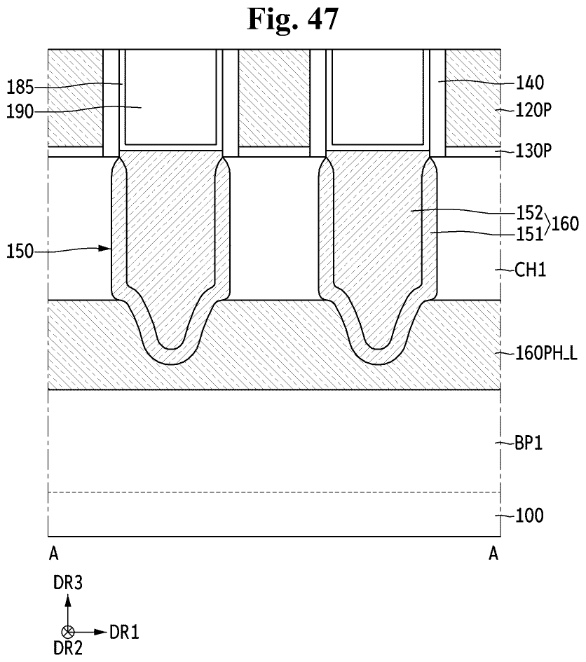

Referring to FIGS. 47 to 51, the dummy gate insulating film 130P and the dummy gate electrode 120P may be removed to expose the first channel pattern CH1 between the gate spacers 140.

The gate electrode 120 and the gate insulating film 130 may be formed on the first channel pattern CH1. The gate electrode 120 that replaces the dummy gate electrode 120P may be formed on the first channel pattern CH1. Also, the gate capping pattern 145 may be formed on the gate electrode 120.

Next, the first front source/drain contact 175 and the front wiring structure 195 may be formed.

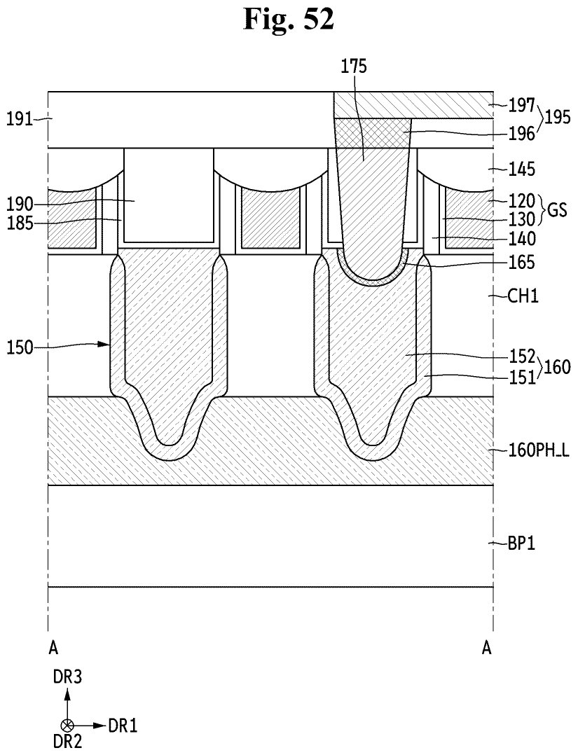

Referring to FIGS. 52 to 54, the substrate 100 may be removed.

The substrate 100 may be removed to expose the lower pattern BP1 and the lower field insulating film 105BP.

Referring to FIGS. 52 to 56, the exposed lower field insulating film 105BP may be removed.

Accordingly, the field insulating liner 106 may be exposed. Also, the side wall of the lower pattern BP1 may be exposed.

By removing the lower field insulating film 105BP, the sacrificial semiconductor film 160PH_L may be exposed in the cross-sectional view taken along C-C of FIG. 1.

Referring to FIGS. 52, 55 to 58, a portion of the exposed sacrificial semiconductor film 160PH_L may be removed to form an active region insulating space 160PH_H between the first channel pattern CH1 and the lower pattern BP1. The active region insulating space 160PH_H may expose the first source/drain pattern 150 and the second source/drain pattern 160, but is not limited thereto.

While the active region insulating space 160PH_H is formed, the first sacrificial semiconductor pattern 160PH may be formed between the first source/drain pattern 150 and the lower pattern BP1, and between the second source/drain pattern 160 and the lower pattern BP1. The first sacrificial semiconductor patterns 160PH adjacent to each other in the first direction DR1 may be separated by the active region insulating space 160PH_H.

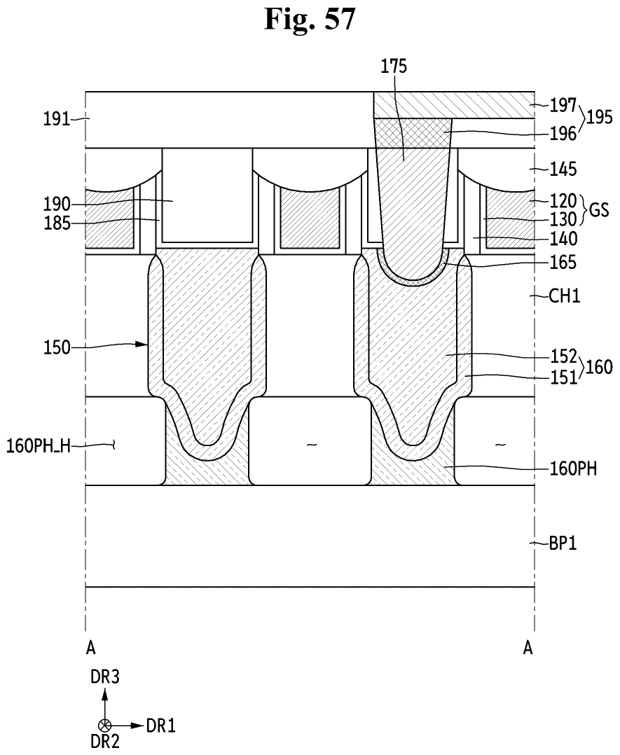

Referring to FIGS. 57 to 61, a second active region insulating pattern CHCT2 may be formed between the first channel pattern CH1 and the lower pattern BP1.

The second active region insulating pattern CHCT2 may fill the active region insulating space 160PH_H between the first channel pattern CH1 and the lower pattern BP1.

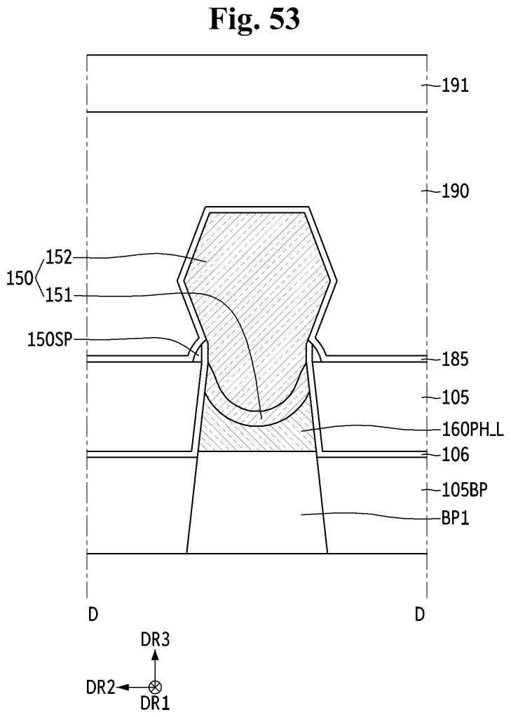

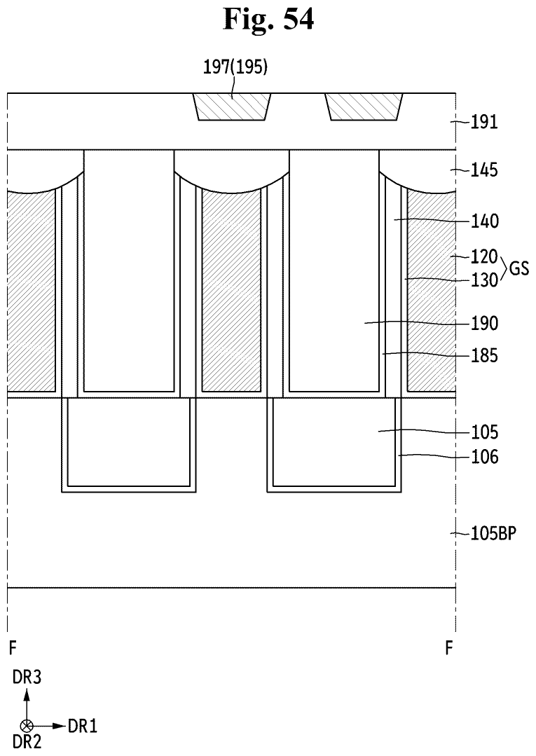

While the second active region insulating pattern CHCT2 is formed, a third back insertion insulating film 293 may be formed in the space from which the lower field insulation film (105BP of FIGS. 53 and 54) is removed. For example, the second active region insulating pattern CHCT2 and the third back insertion insulating film 293 may be formed simultaneously. The third back insertion insulating film 293 may be on (and for example may cover) the side wall of the lower pattern BP1.

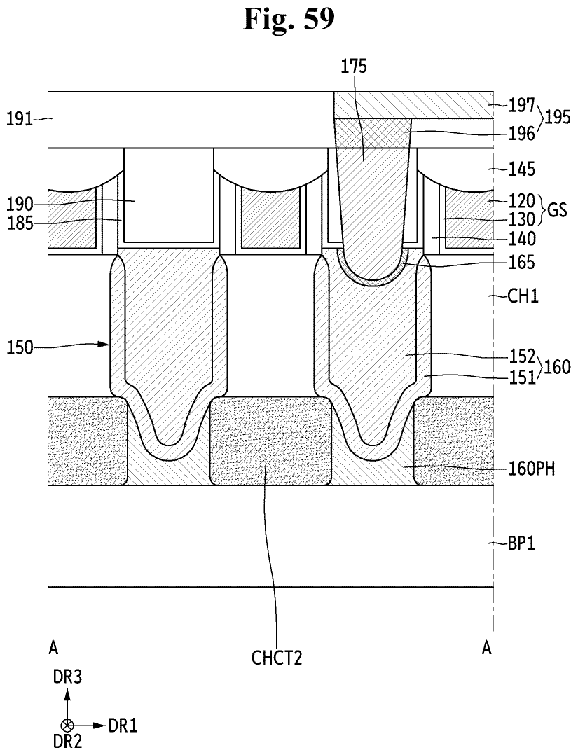

Referring to FIGS. 59 to 63, the lower pattern BP1 may be removed after the third back insertion insulating film 293 is formed.

After the lower pattern BP1 is removed, a second back insertion insulating film 292 is formed in the space from which the lower pattern BP1 is removed. The lower pattern BP1 may be replaced with the second back insertion insulating film 292.

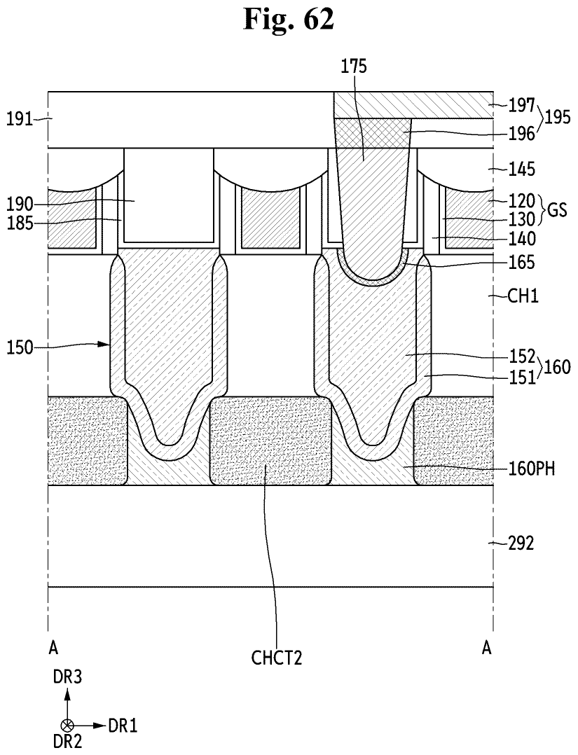

Referring to FIGS. 62 to 65, the back mask pattern BS_MASK may be formed on the second back insertion insulating film 292 and the third back insertion insulating film 293.

A portion of the second back insertion insulating film 292 disposed under the first source/drain pattern 150, and the first sacrificial semiconductor pattern 160PH may be removed, using the back mask pattern BS_MASK as a mask. As a result, a back contact hole 170H that exposes the first source/drain pattern 150 may be formed.

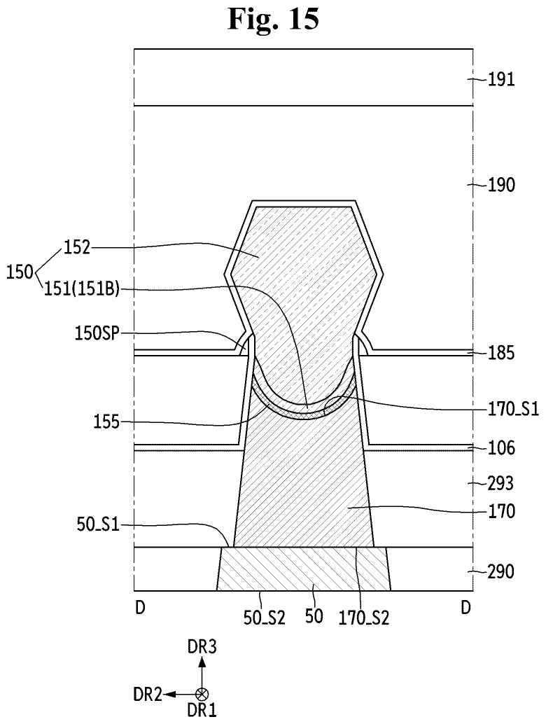

Next, referring to FIGS. 13 and 15, the first back source/drain contact 170 may be formed inside the back contact hole 170H. The first back wiring line 50 connected to the first back source/drain contact 170 may be formed.

While aspects of embodiments have been particularly shown and described, it will be understood that various changes in form and details may be made therein without departing from the spirit and scope of the following claims.

What is claimed is:

1. A semiconductor device comprising:
a back interlayer insulating film;
a back wiring line inside the back interlayer insulating film, wherein the back wiring line comprises a first side and a second side opposite to the first side along a first direction;
a first source/drain pattern on the first side of the back wiring line;
a second source/drain pattern on the first side of the back wiring line, and spaced apart from the first source/drain pattern along a second direction;
a channel pattern between the first source/drain pattern and the second source/drain pattern, and connected to the first source/drain pattern and the second source/drain pattern;
a back source/drain contact between the first source/drain pattern and the back wiring line, and connected to the first source/drain pattern, wherein the back/source drain contact overlaps the first source/drain pattern along the first direction;
a sacrificial semiconductor pattern between the second source/drain pattern and the back wiring line, and in contact with the second source/drain pattern;
a front wiring line on the first source/drain pattern and the second source/drain pattern, and connected to the second source/drain pattern; and
a front source/drain contact between the front wiring line and the second source/drain pattern,
wherein a height from the first side of the back wiring line to a lowermost portion of the first source/drain pattern is greater than a height from the first side of the back wiring line to a lowermost portion of the second source/drain pattern,
wherein the back source/drain contact comprises a first side connected to the first source/drain pattern, and a second side which is opposite to the first side of the back source/drain contact along the first direction and connected to the back wiring line, and
wherein the first side of the back source/drain contact has a concave shape.

2. The semiconductor device of claim 1, wherein the sacrificial semiconductor pattern comprises a contact side that is in contact with the second source/drain pattern, and
wherein a height from the first side of the back wiring line to an uppermost portion of the contact side of the sacrificial semiconductor pattern is equal to or greater than a height from the first side of the back wiring line to an uppermost portion of the back source/drain contact.

3. The semiconductor device of claim 1, wherein the sacrificial semiconductor pattern comprises a bottom side that faces the back wiring line, and
wherein a height from the first side of the back wiring line to the bottom side of the sacrificial semiconductor pattern is less than or equal to the height from the first side of the back wiring line to the lowermost portion of the second source/drain pattern.

4. The semiconductor device of claim 1, further comprising an active region insulating pattern between the channel pattern and the back wiring line, and in contact with the channel pattern,
wherein a height of the active region insulating pattern along the first direction is less than the height of the back source/drain contact along the first direction.

5. The semiconductor device of claim 4, wherein the active region insulating pattern comprises a first side and a second side opposite to the first side along the first direction,
wherein the first side of the active region insulating pattern is contact with the channel pattern, and
wherein the back source/drain contact is in contact with a portion of the second side of the active region insulating pattern.

6. The semiconductor device of claim 4, wherein the height of the active region insulating pattern along the first direction is greater than or equal to the height of the sacrificial semiconductor pattern along the first direction.

7. The semiconductor device of claim 1, further comprising an active region insulating pattern between the channel pattern and the back wiring line, and in contact with the channel pattern,
wherein the channel pattern comprises a plurality of sheet patterns stacked along the first direction,
wherein the plurality of sheet patterns comprises a lowermost sheet pattern closest to the back wiring line, and
wherein the active region insulating pattern penetrates the lowermost sheet pattern.

8. The semiconductor device of claim 7, further comprising an inner gate structure between adjacent sheet patterns along the first direction, wherein the inner gate structure comprises a gate electrode and a gate insulating film,
wherein the active region insulating pattern is in contact with the inner gate structure.

9. The semiconductor device of claim 7, wherein the height of the active region insulating pattern along the first direction is greater than the height of the back source/drain contact along the first direction.

10. A semiconductor device comprising:
a back interlayer insulating film;
a back wiring line inside the back interlayer insulating film, and comprises a first side and a second side opposite to the first side along a first direction;
a first source/drain pattern on the first side of the back wiring line;
a second source/drain pattern on the first side of the back wiring line, and spaced apart from the first source/drain pattern along a second direction;
a channel pattern between the first source/drain pattern and the second source/drain pattern, and connected to the first source/drain pattern and the second source/drain pattern;
a back source/drain contact between the first source/drain pattern and the back wiring line, and connected to the first source/drain pattern, wherein the back source/drain contact overlaps the first source/drain pattern along the first direction;
a back contact silicide film between the back source/drain contact and the first source/drain pattern;
a sacrificial semiconductor pattern between the second source/drain pattern and the back wiring line, and in contact with the second source/drain pattern;
a front wiring line on the first source/drain pattern and the second source/drain pattern, and connected to the second source/drain pattern; and
a front source/drain contact between the front wiring line and the second source/drain pattern,
wherein at least one of the first source/drain pattern and the second source/drain pattern comprises a semiconductor liner film, and a semiconductor filling film on the semiconductor liner film,
wherein the semiconductor liner film comprises an outer side face that is in contact with the channel pattern, and an inner side face that is in contact with the semiconductor filling film,
wherein the semiconductor filling film fills a liner recess defined by the inner side face of the semiconductor liner film, and
wherein the back contact silicide film is in contact with the semiconductor liner film of the first source/drain pattern, and is not in contact with the semiconductor filling film of the first source/drain pattern.

11. The semiconductor device of claim 10, wherein the semiconductor liner film of the first source/drain pattern extends up to an upper side of the channel pattern.

12. The semiconductor device of claim 10, wherein the back source/drain contact comprises a first side connected to the first source/drain pattern, and a second side opposite to the first side of the back source/drain contact along the first direction and connected to the back wiring line, and
wherein the first side of the back source/drain contact has a concave shape.

13. The semiconductor device of claim 10, wherein in the first source/drain pattern, the semiconductor liner film comprises a bottom portion that is in contact with the back contact silicide film, and a side wall portion that is in contact with the channel pattern,
wherein a germanium fraction of the bottom portion of the semiconductor liner film is equal to a germanium fraction of the side wall portion of the semiconductor liner film, and
wherein a concentration of impurities contained in the bottom portion of the semiconductor liner film is higher than the concentration of impurities contained in the side wall portion of the semiconductor liner film.

14. The semiconductor device of claim 10, wherein a germanium fraction of the sacrificial semiconductor pattern is greater than a germanium fraction of the semiconductor liner film.

15. The semiconductor device of claim 10, wherein the sacrificial semiconductor pattern comprises a contact side that is in contact with the second source/drain pattern, and
wherein a height from the first side of the back wiring line to an uppermost portion of a contact side of the sacrificial semiconductor pattern is equal to or greater than a height from the first side of the back wiring line to an uppermost portion of the back source/drain contact.

16. The semiconductor device of claim 10, further comprising an active region insulating pattern between the channel pattern and the back wiring line, and in contact with the channel pattern,
wherein a height of the active region insulating pattern along the first direction is less than a height of the back source/drain contact along the first direction.

17. The semiconductor device of claim 10, further comprising an active region insulating pattern between the channel pattern and the back wiring line, and in contact with the channel pattern,
wherein the channel pattern comprises a plurality of sheet patterns stacked along the first direction,
wherein the plurality of sheet patterns comprises a lowermost sheet pattern closest to the back wiring line, and
wherein the active region insulating pattern penetrates the lowermost sheet pattern.

18. A semiconductor device comprising:
a back interlayer insulating film;
a back wiring line inside the back interlayer insulating film, wherein the back wiring line comprises a first side and a second side opposite the first side along a first direction;
a first source/drain pattern on the first side of the back wiring line;
a second source/drain pattern on the first side of the back wiring line, and spaced apart from the first source/drain pattern along a second direction;
a channel pattern between the first source/drain pattern and the second source/drain pattern, and connected to the first source/drain pattern and the second source/drain pattern;
a back source/drain contact between the first source/drain pattern and the back wiring line, and connected to the first source/drain pattern, wherein the back source/drain contact overlaps the first source/drain pattern along the first direction;
a sacrificial semiconductor pattern between the second source/drain pattern and the back wiring line, and in contact with the second source/drain pattern;
a front wiring line on the first source/drain pattern and the second source/drain pattern, and connected to the second source/drain pattern; and
a front source/drain contact between the front wiring line and the second source/drain pattern,
wherein the sacrificial semiconductor pattern comprises a contact side that is in contact with the second source/drain pattern,
wherein a height from the first side of the back wiring line to an uppermost portion of the contact side of the sacrificial semiconductor pattern is greater than a height from the first side of the back wiring line to a lowermost portion of the second source/drain pattern,
wherein the height from the first side of the back wiring line to the uppermost portion of the contact side of the sacrificial semiconductor pattern is equal to or greater than a height from the first side of the back wiring line to an uppermost portion of the back source/drain contact,
wherein the back source/drain contact comprises a first side connected to the first source/drain pattern, and a second side which is opposite to the first side of the back source/drain contact along the first direction and connected to the back wiring line, and
wherein the first side of the back source/drain contact has a concave shape.

19. The semiconductor device of claim 18, further comprising an active region insulating pattern between the channel pattern and the back wiring line, and in contact with the channel pattern,
wherein a height of the active region insulating pattern along the first direction is less than the height of the back source/drain contact along the first direction.

20. The semiconductor device of claim 18, further comprising an active region insulating pattern between the channel pattern and the back wiring line, and in contact with the channel pattern,
wherein the channel pattern comprises a plurality of sheet patterns stacked along the first direction,
wherein the plurality of sheet patterns comprises a lowermost sheet pattern closest to the back wiring line, and
wherein the active region insulating pattern penetrates the lowermost sheet pattern.
